(19) United States
(12) Patent Application Publication
(10) Pub. No.: US 2005/0128539 A1
(43) Pub. Date: Jun. 16, 2005

(54) Image processing method, image processing apparatus and image recording apparatus

(75) Inventors: Hiroaki Takano, Tokyo (JP); Tsukasa Ito, Tokyo (JP)

Correspondence Address: MUSERLIAN, LUCAS AND MERCANTI, LLP, 475 PARK AVENUE SOUTH, 15TH FLOOR, NEW YORK, NY, 10016, US

(73) Assignee: Konica Minolta Photo Imaging, Inc., Tokyo (JP)

(21) Appl. No.: 10/832,067

(22) Filed: Apr. 26, 2004

(30) Foreign Application Priority Data
May 9, 2003 (JP) JP2003-131371

(51) Int. Cl. G03F 3/08

(52) U.S. Cl. 358/521

(57) ABSTRACT

There is described an image-processing method for generating output-referred image data. The method includes the steps of: designating a hardness adjusting value for the output-referred image data; changing a gradation conversion curve based on the hardness adjusting value, so as to generate a first-revised gradation conversion curve; designating a brightness adjusting value for the output-referred image data; changing the first-revised gradation conversion curve, based on the brightness adjusting value, so as to generate a second-revised gradation conversion curve; and generating the output-referred image data, based on the second-revised gradation conversion curve. The first-revised gradation conversion curve is generated by modifying a shape of the gradation conversion curve residing in a region other than a specific region, based on the hardness adjusting value of the output-referred image data. The second-revised gradation conversion curve is generated by modifying a shape of the first-revised gradation conversion curve, based on the brightness adjusting value.

### BACKGROUND OF THE INVENTION

The present invention relates to an image processing method and an image processing apparatus for applying optimization processing to form an output-referred image on an output medium from scene-referred image data, and an image recording apparatus for forming an output-referred image on the output medium.

At present, the digital image data captured by an image-capturing apparatus, such as a digital camera, etc., is distributed through such a memory device as a CD-R (Compact Disk Recordable), floppy disk (registered trade name) and memory card or the Internet, and is displayed on such a display monitor as a CRT (Cathode Ray Tube), liquid crystal display and plasma display or a small-sized liquid crystal monitor display device of a cellular phone, or is printed out as a hard copy image using such an output device as a digital printer, inkjet printer and thermal printer. In this way, display and print methods have been diversified in recent years.

When digital image data is displayed or printed out for viewing, it is a common practice to provide various types of image processing typically represented by gradation adjustment, brightness adjustment, color balancing and enhancement of sharpness to ensure that a desired image quality is obtained on the display monitor used for viewing or on the hard copy.

In response to such varied display and printing methods, efforts have been made to improve the general versatility of digital image data captured by an image-capturing apparatus. As part of these efforts, an attempt has been made to standardize the color space represented by digital RGB (Red, Green and Blue) signals into the color space that does not depend on characteristics of an image-capturing apparatus. At present, large amounts of digital image data have adopted the sRGB (See Multimedia Systems and Equipment—Color Measurement and Management—Part 2-1: Color Management—Default RGB Color Space—sRGB” IEC61966-2-1) as a standardized color space. The color space of this sRGB has been established to meet the color reproduction area for a standard CRT display monitor.

Generally, a digital camera is equipped with an image sensor, serving as an image-capturing device (CCD type image sensor, hereinafter also referred to as “CCD” for simplicity) having a photoelectric conversion function with color sensitivity provided by a combination of a CCD (charge coupled device), a charge transfer device and a mosaic color filter. The digital image data output from the digital camera is obtained after the electric original signal gained by conversion via the CCD has been corrected by the photoelectric conversion function of the image sensor, (for instance, an image-processing operation, such as gradation correction, spectral sensitivity, crosstalk correction, dark current noise control, sharpening, white balance adjustment and color saturation adjustment) and processing of file conversion and compression into the predetermined data format standardized to permit reading and display by image editing software.

The above-mentioned data format widely known includes Baseline Tiff Rev. 6.0 RGB Full Color Image adopted as a non-compressed file of the Exif (Exchangeable Image File Format) file and compressed data file format conforming to the JPEG format. The Exif file conforms to the above-mentioned sRGB, and the correction of the photoelectric conversion function of the above-mentioned image-capturing element is established so as to ensure the most suitable image quality on the display monitor conforming to the sRGB.

For example, if a digital camera has the function of writing into the header of the digital image data the tag information for display in the standard color space (hereinafter referred to as “monitor profile”) of the display monitor conforming to the sRGB signal, and accompanying information indicating the device dependent information such as the number of pixels, pixel arrangement and number of bits per pixel as meta-data, and if only such a data format is adopted, then the tag information can be analyzed by the image edit software (e.g. Photoshop by Adobe for displaying the above-mentioned digital image data on the digital display monitor, conversion of the monitor profile into the sRGB can be prompted, and modification can be processed automatically. This capability reduces the differences in apparatus characteristics among different displays, and permits viewing of the digital image data photographed by a digital camera under the optimum condition.

In addition to the above-mentioned information dependent on device type, the above-mentioned accompanying information includes; information directly related to the camera type (device type) such as a camera name and code number, information on photographing conditions such as exposure time, shutter speed, f-stop number (F number), ISO sensitivity, brightness value, subject distance range, light source, on/off status of a stroboscopic lamp, subject area, white balance, zoom scaling factor, subject configuration, photographing scene type, the amount of reflected light of the stroboscopic lamp source and color saturation for photographing, and tags (codes) for indicating the information related to a subject. The image editing software and output device have a function of reading the above-mentioned accompanying information and making the quality of hardware image more suitable.

The image displayed on such a display device as a CRT display monitor and the hard copy image printed by various printing devices have different color reproduction areas depending on the configuration of the phosphor or color material to be used. For example, the color reproduction area of the CRT display monitor corresponding to the sRGB standard space has a wide bright green and blue area. It contains the area that cannot be reproduced by the hard copy formed by a silver halide photographic printer, ink-jet printer and conventional printer. Conversely, the cyan area of the conventional printing or inkjet printing and the yellow area of the silver halide photographic printing contain the area that cannot be reproduced by the CRT display monitor corresponding to the sRGB standard color space. (For example, see “Fine imaging and digital photographing” edited by the Publishing Commission of the Japan Society of Electrophotography, Corona Publishing Co., P. 444). In the meantime, some of the scenes of the subject to be photographed may contain the color in the area that cannot be reproduced in any of these areas for color reproduction.

As described above, the color space (including the sRGB) optimized on the basis of display and printing by a specific device is accompanied by restrictions in the color gamut where recording is possible. So when recording the information picked up by a photographing device, it is necessary to make adjustment of mapping by compressing the information into the color gamut where recording is allowed. The simplest way is provided by clipping where the color chromaticity point outside the color gamut where recording is possible is mapped onto the boundary of the nearest color gamut. This causes the gradation outside the color gamut to be collapsed, and the image will give a sense of incompatibility to the viewer. To avoid this problem, non-liner compression method is generally used. In this method, the chromaticity point in the area where chroma is high in excess of an appropriate threshold value is compressed smoothly according to the size of the chroma. As a result, chroma is compressed and recording is carried out even at the chromaticity point inside the color gamut where recording is possible. (For the details of the procedure of mapping the color gamut, see “Fine imaging and digital photographing” edited by the Publishing Commission of the Japan Society of Electrophotography, Corona Publishing Co., P. 447, for example).

The image displayed on such a display device as a CRT display monitor, the hard copied image printed by various types of printing devices, or color space (including sRGB) optimized on the basis of display and printing by these devices are restricted to the conditions where the area of brightness that allows recording and reproduction is of the order of about 100 to 1. By contrast, however, the scene of the subject to be photographed has a wide area of brightness, and it often happens that the order of several thousands to 1 is reached outdoors. (See “Handbook on Science of Color, New Version, 2nd Print” by Japan Society for Science of Colors, Publishing Society of the University of Tokyo, P. 926, for example). Accordingly, when recording the information gained by the image sensor, compression is also necessary for brightness. In this processing, adequate conditions must be set for each image in conformity to the dynamic range of the scene to be photographed, and the range of brightness for the main subject in the scene to be photographed.

However, when compression has been carried out for the color gamut and brightness area as described above, information on gradation prior to compression or information prior to clipping is lost immediately due to the principle of the digital image to be recorded in terms of the discrete value. The original state cannot be recovered. This imposes a big restriction on the general versatility of high-quality digital image.

For example, when the image recorded in the sRGB standard color space is printed, mapping must be carried out again based on the differences between the sRGB standard color space and the area for color reproduction of the printing device. For the image recorded in the sRGB standard color space, however, the information on gradation in the area compressed at a time of recording is lost. So the smoothness of gradation is deteriorated as compared to the case where the information captured by the photographing device is mapped directly in the area for color reproduction of the printing device. Further, if gradation compression conditions are not adequate at a time of recording, and there are problems such as a whitish picture, dark face, deformed shadow and conspicuous white skipping in the highlighted area, improvement is very inadequate as compared to the case where the new image is created again from the information gained by the photographing device, even if the gradation setting is changed to improve the image. This is because information on gradation prior to compression, and information on the portion subjected to deformation or white skipping have been already lost.

As a solution of the above-mentioned problems, the art of storing the process of image editing as a backup data and returning it to the state prior to editing whenever required has long been known. For example, Patent Document 1 discloses a backup device wherein, when the digital image is subjected to local modification by image processing, the image data on the difference between the digital image data before image processing and that after image processing is saved as backup data. Further, Patent Document 2 discloses a method for recovering the digital image data before editing, by saving the image data on the difference between the digital image data before image processing and that after image processing. Although these technologies have been effective from the viewpoint of preventing information from being lost, it has been a problem that the number of sheets, which can be photographed by a camera, is reduced with the increase in the amount of data recorded in the media.

The problems introduced above are caused by the procedure where the information on the wide color gamut and brightness area gained by a photographing device is recorded after having being compressed into the output-referred image data in the state optimized by assuming an image to be viewed. By contrast, if the information on the wide color gamut and brightness area gained by a photographing device is recorded as scene-referred image data that is not compressed, then inadvertent loss of information can be prevented. The standard color space suited to record such scene-referred image data is proposed, for example, by RIMM RGB (Reference Input Medium Metric RGB) and ERIMM RGB (Extended Reference Input Medium Metric RGB). (See the Journal of Imaging Science and Technology, Vol. 45 p p. 418 to 426 (2001)).

Patent Document 3 discloses an image processing apparatus characterized by two modes; a mode of recording in the form of an image signal displayed on the display means and a mode of recording in the form of captured image signal. The form of image signal in the latter case is generally called RAW data. Using the special-purpose application software (called “development software”), such digital image data can be converted into output-referred image data of the above-mentioned Exif file or the like for display or printing (called “electronic development” or simply “development”). Since the RAW data retains all information at a time of photographing, it permits output-referred image data to be remade. If other color system files such as CMYK are created directly, there will no inadvertent modification of the color system due to the difference in color gamut from the display monitor (sRGB).

[Patent Document 1]
Tokkaihei 7-57074

[Patent Document 2]
Tokkai 2001-94778

[Patent Document 3]
Tokkaihei 11-261933

When converting scene-referred image data, for example, to the optimum output-referred image data on a display monitor using the aforementioned technique, it is necessary to set a gradation conversion curve or to adjust the chroma using special-purpose application software, similarly to the case of raw data. The gradation conversion curve is commonly set by mouse operation using the user interface function that visually adjusts the shape of a curve. However, setting of a gradation conversion curve involves the adjustment of the hardness and brightness on the shadow side, intermediate region and highlighted side at the same time. This work requires a high level of skill. Further, setting of the gradation conversion curve variously depends on the category of the subject or photographic conditions (e.g. shooting in flash mode and a backlighted subject). In the case of conformance to sRGB and other standards as in a CRT display, the setting of the gradation conversion curve is applicable to very wide varieties of cases, and this will make it easy for the manufacturer to determine recommended settings. However, when an output-referred image is formed for a silver halide printer and inkjet printer, various fluctuation factors must be taken into account. There are very few cases where recommended setting is satisfactory. In addition, there are differences in the preference of users, and adjustment by the user is essential. According to the prior art, heavy loads are imposed on the user in the step of gradation conversion curve setting for conversion from the scene-referred image data to the output-referred image. Thus, the problem with the prior art is that the gradation conversion curve cannot easily be set.

### SUMMARY OF THE INVENTION

To overcome the abovementioned drawbacks in conventional image-processing methods and apparatus, it is an object of the present invention to provide image-processing methods and apparatus, image-recording apparatus and computer programs, which make it possible to implement an image processing for reducing the workload in the setting of a gradation conversion curve when converting the scene-referred image data to the output-referred image data.

Accordingly, to overcome the cited shortcomings, the abovementioned object of the present invention can be attained by image-processing methods and apparatus, image-recording apparatus and computer programs described as follow.

(1) An image-processing method for generating output-referred image data by applying an optimization processing, for optimizing an output image to be formed on an outputting medium, to scene-referred image data, the image-processing method comprising the steps of: designating a hardness adjusting value for the output-referred image data; changing a gradation conversion curve, which is defined for every outputting medium in advance and represents a conversion table for converting the scene-referred image data to the output-referred image data, based on the hardness adjusting value, so as to generate a first-revised gradation conversion curve; designating a brightness adjusting value for the output-referred image data; changing the first-revised gradation conversion curve, based on the brightness adjusting value, so as to generate a second-revised gradation conversion curve; and generating the output-referred image data, based on the second-revised gradation conversion curve; wherein the first-revised gradation conversion curve is generated by modifying a shape of the gradation conversion curve residing in a region other than a specific region, which serves as a fixed region including a predetermined position on the gradation conversion curve, based on the hardness adjusting value of the output-referred image data; and wherein the second-revised gradation conversion curve is generated by modifying a shape of the first-revised gradation conversion curve in such a manner that the specific region moves on a predetermined curve defined in advance, based on the brightness adjusting value.

(2) An image-processing method for generating output-referred image data by applying an optimization processing, for optimizing an output image to be formed on an outputting medium, to scene-referred image data, the image-processing method comprising the steps of: determining a hardness adjusting value for the output-referred image data, corresponding to a kind of a subject to be included in the output image; changing a gradation conversion curve, which is defined for every outputting medium in advance and represents a conversion table for converting the scene-referred image data to the output-referred image data, based on the hardness adjusting value, so as to generate a first-revised gradation conversion curve; determining a brightness adjusting value for the output-referred image data, corresponding to an image-capturing condition; changing the first-revised gradation conversion curve, based on the brightness adjusting value, so as to generate a second-revised gradation conversion curve; and generating the output-referred image data, based on the second-revised gradation conversion curve; wherein the first-revised gradation conversion curve is generated by modifying a shape of the gradation conversion curve residing in a region other than a specific region, which serves as a fixed region including a predetermined position on the gradation conversion curve, based on the hardness adjusting value of the output-referred image data; and wherein the second-revised gradation conversion curve is generated by modifying a shape of the first-revised gradation conversion curve in such a manner that the specific region moves on a predetermined curve defined in advance, based on the brightness adjusting value.

(3) An image-processing method for generating output-referred image data by applying an optimization processing, for optimizing an output image to be formed on an outputting medium, to scene-referred image data, the image-processing method comprising the steps of: determining a hardness adjusting value and a brightness adjusting value for the output-referred image data, corresponding to a specific combination of a kind of a subject to be included in the output image and an image-capturing condition; changing a gradation conversion curve, which is defined for every outputting medium in advance and represents a conversion table for converting the scene-referred image data to the output-referred image data, based on the hardness adjusting value, so as to generate a first-revised gradation conversion curve; changing the first-revised gradation conversion curve, based on the brightness adjusting value, so as to generate a second-revised gradation conversion curve; and generating the output-referred image data, based on the second-revised gradation conversion curve; wherein the first-revised gradation conversion curve is generated by modifying a shape of the gradation conversion curve residing in a region other than a specific region, which serves as a fixed region including a predetermined position on the gradation conversion curve, based on the hardness adjusting value of the output-referred image data; and wherein the second-revised gradation conversion curve is generated by modifying a shape of the first-revised gradation conversion curve in such a manner that the specific region moves on a predetermined curve defined in advance, based on the brightness adjusting value.

(4) An image-processing method for generating output-referred image data by applying an optimization processing, for optimizing an output image to be formed on an outputting medium, to scene-referred image data, the image-processing method comprising the steps of: designating a hardness adjusting value for the output-referred image data; changing a gradation conversion curve, which is defined for every outputting medium in advance and represents a conversion table for converting the scene-referred image data to the output-referred image data, based on the hardness adjusting value, so as to generate a first-revised gradation conversion curve; designating a brightness adjusting value for the output-referred image data; changing the first-revised gradation conversion curve, based on the brightness adjusting value, so as to generate a second-revised gradation conversion curve; and determining a chroma adjusting value for the output-referred image data, based on the hardness adjusting value designated in the designating step; generating the output-referred image data, based on the second-revised gradation conversion curve and the chroma adjusting value determined in the determining step; wherein the first-revised gradation conversion curve is generated by modifying a shape of the gradation conversion curve residing in a region other than a specific region, which serves as a fixed region including a predetermined position on the gradation conversion curve, based on the hardness adjusting value of the output-referred image data; and wherein the second-revised gradation conversion curve is generated by modifying a shape of the first-revised gradation conversion curve in such a manner that the specific region moves on a predetermined curve defined in advance, based on the brightness adjusting value.

(5) The image-processing method of item 2, further comprising the step of: determining a hardness adjusting value and a brightness adjusting value for the output-referred image data, corresponding to a specific combination of a kind of a subject to be included in the output image and an image-capturing condition; wherein the gradation conversion curve is changed to the first-revised gradation conversion curve, based on the hardness adjusting value determined in the determining step; and wherein the first-revised gradation conversion curve is changed to the second-revised gradation conversion curve, based on the brightness adjusting value determined in the determining step.

(6) The image-processing method of item 2, further comprising the step of: determining a chroma adjusting value for the output-referred image data, based on the hardness adjusting value designated in the designating step; wherein the output-referred image data are generated, based on the second-revised gradation conversion curve and the chroma adjusting value determined in the determining step.

(7) The image-processing method of item 3, further comprising the step of: determining a chroma adjusting value for the output-referred image data, based on the hardness adjusting value determined in the determining step; wherein the output-referred image data are generated, based on the second-revised gradation conversion curve and the chroma adjusting value determined in the determining step.

(8) The image-processing method of item 5, further comprising the step of: determining a chroma adjusting value for the output-referred image data, based on the hardness adjusting value designated in the designating step; wherein the output-referred image data are generated, based on the second-revised gradation conversion curve and the chroma adjusting value determined in the determining step.

(9) The image-processing method of item 3, wherein the kind of subject is a portrait and the image-capturing condition is a backlight.

(10) The image-processing method of item 4, wherein, when the hardness adjusting value is set at zero, the brightness adjusting value is set at such a value that chroma components of the output-referred image data are emphasized.

(11) The image-processing method of item 2, wherein the kind of subject includes at least anyone of a portrait, a landscape and a still life.

(12) The image-processing method of item 2, wherein the image-capturing condition includes at least anyone of a backlight and a strobe lighting.

(13) The image-processing method of item 1, wherein, when an input-output value of the gradation conversion curve is L*, the predetermined position included in the specific region is located at such a position that input value L* is smaller than 50 and equal to or greater than 40.

(14) The image-processing method of item 1, wherein initial values of hardness and brightness on the gradation conversion curve, which is defined for every outputting medium in advance, are stored in a storage, while correlating them with every one of users.

(15) An image-processing apparatus for generating output-referred image data by applying an optimization processing, for optimizing an output image to be formed on an outputting medium, to scene-referred image data, the image-processing apparatus comprising: a first-designating section to designate a hardness adjusting value for the output-referred image data; a first-changing section to change a gradation conversion curve, which is defined for every outputting medium in advance and represents a conversion table for converting the scene-referred image data to the output-referred image data, based on the hardness adjusting value, so as to generate a first-revised gradation conversion curve; a second-designating section to designate a brightness adjusting value for the output-referred image data; a second-changing section to change the first-revised gradation conversion curve, based on the brightness adjusting value, so as to generate a second-revised gradation conversion curve; and a generating section to generate the output-referred image data, based on the second-revised gradation conversion curve; wherein the first-changing section generates the first-revised gradation conversion curve by modifying a shape of the gradation conversion curve residing in a region other than a specific region, which serves as a fixed region including a predetermined position on the gradation conversion curve, based on the hardness adjusting value of the output-referred image data; and wherein the first-changing section generates the second-revised gradation conversion curve by modifying a shape of the first-revised gradation conversion curve in such a manner that the specific region moves on a predetermined curve defined in advance, based on the brightness adjusting value.

(16) An image-processing apparatus for generating output-referred image data by applying an optimization processing, for optimizing an output image to be formed on an outputting medium, to scene-referred image data, the image-processing apparatus comprising: a hardness-determining section to determine a hardness adjusting value for the output-referred image data, corresponding to a kind of a subject to be included in the output image; a first-changing section to change a gradation conversion curve, which is defined for every outputting medium in advance and represents a conversion table for converting the scene-referred image data to the output-referred image data, based on the hardness adjusting value, so as to generate a first-revised gradation conversion curve; a brightness-determining section to determine a brightness adjusting value for the output-referred image data, corresponding to an image-capturing condition; a second-changing section to change the first-revised gradation conversion curve, based on the brightness adjusting value, so as to generate a second-revised gradation conversion curve; and a generating section to generate the output-referred image data, based on the second-revised gradation conversion curve; wherein the first-changing section generates the first-revised gradation conversion curve by modifying a shape of the gradation conversion curve residing in a region other than a specific region, which serves as a fixed region including a predetermined position on the gradation conversion curve, based on the hardness adjusting value of the output-referred image data; and wherein the first-changing section generates the second-revised gradation conversion curve by modifying a shape of the first-revised gradation conversion curve in such a manner that the specific region moves on a predetermined curve defined in advance, based on the brightness adjusting value.

(17) An image-processing apparatus for generating output-referred image data by applying an optimization processing, for optimizing an output image to be formed on an outputting medium, to scene-referred image data, the image-processing apparatus comprising: a determining section to determine a hardness adjusting value and a brightness adjusting value for the output-referred image data, corresponding to a specific combination of a kind of a subject to be included in the output image and an image-capturing condition; a first-changing section to change a gradation conversion curve, which is defined for every outputting medium in advance and represents a conversion table for converting the scene-referred image data to the output-referred image data, based on the hardness adjusting value, so as to generate a first-revised gradation conversion curve; a second-changing section to change the first-revised gradation conversion curve, based on the brightness adjusting value, so as to generate a second-revised gradation conversion curve; and a generating section to generate the output-referred image data, based on the second-revised gradation conversion curve; wherein the first-changing section generates the first-revised gradation conversion curve by modifying a shape of the gradation conversion curve residing in a region other than a specific region, which serves as a fixed region including a predetermined position on the gradation conversion curve, based on the hardness adjusting value of the output-referred image data; and wherein the first-changing section generates the second-revised gradation conversion curve by modifying a shape of the first-revised gradation conversion curve in such a manner that the specific region moves on a predetermined curve defined in advance, based on the brightness adjusting value.

(18) An image-processing apparatus for generating output-referred image data by applying an optimization processing, for optimizing an output image to be formed on an outputting medium, to scene-referred image data, the image-processing apparatus comprising: a hardness-designating section to designate a hardness adjusting value for the output-referred image data; a first-changing section to change a gradation conversion curve, which is defined for every outputting medium in advance and represents a conversion table for converting the scene-referred image data to the output-referred image data, based on the hardness adjusting value, so as to generate a first-revised gradation conversion curve; a brightness-designating section to designate a brightness adjusting value for the output-referred image data; a second-changing section to change the first-revised gradation conversion curve, based on the brightness adjusting value, so as to generate a second-revised gradation conversion curve; and a chroma-determining section to determine a chroma adjusting value for the output-referred image data, based on the hardness adjusting value designated by the hardness-designating section; a generating section to generate the output-referred image data, based on the second-revised gradation conversion curve and the chroma adjusting value determined by the chroma-determining section; wherein the first-changing section generates the first-revised gradation conversion curve by modifying a shape of the gradation conversion curve residing in a region other than a specific region, which serves as a fixed region including a predetermined position on the gradation conversion curve, based on the hardness adjusting value of the output-referred image data; and wherein the first-changing section generates the second-revised gradation conversion curve by modifying a shape of the first-revised gradation conversion curve in such a manner that the specific region moves on a predetermined curve defined in advance, based on the brightness adjusting value.

(19) The image-processing apparatus of item 16, further comprising: a determining section to determine a hardness adjusting value and a brightness adjusting value for the output-referred image data, corresponding to a specific combination of a kind of a subject to be included in the output image and an image-capturing condition; wherein the first-changing section changes the gradation conversion curve to the first-revised gradation conversion curve, based on the hardness adjusting value determined by the determining section; and wherein the second-changing section changes the first-revised gradation conversion curve to the second-revised gradation conversion curve, based on the brightness adjusting value determined by the determining section.

(20) The image-processing apparatus of item 16, further comprising: a chroma-determining section to determine a chroma adjusting value for the output-referred image data, based on the hardness adjusting value determined by the hardness-determining section; wherein the generating section generates the output-referred image data, based on the second-revised gradation conversion curve and the chroma adjusting value determined by the chroma-determining section.

(21) The image-processing apparatus of item 17, further comprising: a chroma-determining section to determine a chroma adjusting value for the output-referred image data, based on the hardness adjusting value determined by the hardness-determining section; wherein the generating section generates the output-referred image data, based on the second-revised gradation conversion curve and the chroma adjusting value determined by the chroma-determining section.

(22) The image-processing apparatus of item 19, further comprising: a chroma-determining section to determine a chroma adjusting value for the output-referred image data, based on the hardness adjusting value determined by the hardness-determining section and the determining section; wherein the generating section generates the output-referred image data, based on the second-revised gradation conversion curve and the chroma adjusting value determined by the chroma-determining section.

(23) The image-processing apparatus of item 17, wherein the kind of subject is a portrait and the image-capturing condition is a backlight.

(24) The image-processing apparatus of item 18, wherein, when the hardness adjusting value is set at zero, the brightness adjusting value is set at such a value that chroma components of the output-referred image data are emphasized.

(25) The image-processing apparatus of item 16, wherein the kind of subject includes at least anyone of a portrait, a landscape and a still life.

(26) The image-processing apparatus of item 16, wherein the image-capturing condition includes at least anyone of a backlight and a strobe lighting.

(27) The image-processing method of item 15, wherein, when an input-output value of the gradation conversion curve is L*, the predetermined position included in the specific region is located at such a position that input value L* is smaller than 50 and equal to or greater than 40.

(28) The image-processing apparatus of item 15, further comprising: a storage section to store initial values of hardness and brightness on the gradation conversion curve, which is defined for every outputting medium in advance, while correlating them with every one of users.

(29) An image-recording apparatus for generating output-referred image data by applying an optimization processing, for optimizing an output image to be formed on an outputting medium, to scene-referred image data, and then, recording the output image based on the output-referred image data onto the outputting medium, the image-recording apparatus comprising: a first-designating section to designate a hardness adjusting value for the output-referred image data; a first-changing section to change a gradation conversion curve, which is defined for every outputting medium in advance and represents a conversion table for converting the scene-referred image data to the output-referred image data, based on the hardness adjusting value, so as to generate a first-revised gradation conversion curve; a second-designating section to designate a brightness adjusting value for the output-referred image data; a second-changing section to change the first-revised gradation conversion curve, based on the brightness adjusting value, so as to generate a second-revised gradation conversion curve; and a generating section to generate the output-referred image data, based on the second-revised gradation conversion curve; wherein the first-changing section generates the first-revised gradation conversion curve by modifying a shape of the gradation conversion curve residing in a region other than a specific region, which serves as a fixed region including a predetermined position on the gradation conversion curve, based on the hardness adjusting value of the output-referred image data; and wherein the first-changing section generates the second-revised gradation conversion curve by modifying a shape of the first-revised gradation conversion curve in such a manner that the specific region moves on a predetermined curve defined in advance, based on the brightness adjusting value.

(30) An image-recording apparatus for generating output-referred image data by applying an optimization processing, for optimizing an output image to be formed on an outputting medium, to scene-referred image data, and then, recording the output image based on the output-referred image data onto the outputting medium, the image-recording apparatus comprising: a hardness-determining section to determine a hardness adjusting value for the output-referred image data, corresponding to a kind of a subject to be included in the output image; a first-changing section to change a gradation conversion curve, which is defined for every outputting medium in advance and represents a conversion table for converting the scene-referred image data to the output-referred image data, based on the hardness adjusting value, so as to generate a first-revised gradation conversion curve; a brightness-determining section to determine a brightness adjusting value for the output-referred image data, corresponding to an image-capturing condition; a second-changing section to change the first-revised gradation conversion curve, based on the brightness adjusting value, so as to generate a second-revised gradation conversion curve; and a generating section to generate the output-referred image data, based on the second-revised gradation conversion curve; wherein the first-changing section generates the first-revised gradation conversion curve by modifying a shape of the gradation conversion curve residing in a region other than a specific region, which serves as a fixed region including a predetermined position on the gradation conversion curve, based on the hardness adjusting value of the output-referred image data; and wherein the first-changing section generates the second-revised gradation conversion curve by modifying a shape of the first-revised gradation conversion curve in such a manner that the specific region moves on a predetermined curve defined in advance, based on the brightness adjusting value.

(31) An image-recording apparatus for generating output-referred image data by applying an optimization processing, for optimizing an output image to be formed on an outputting medium, to scene-referred image data, and then, recording the output image based on the output-referred image data onto the outputting medium, the image-recording apparatus comprising: a determining section to determine a hardness adjusting value and a brightness adjusting value for the output-referred image data, corresponding to a specific combination of a kind of a subject to be included in the output image and an image-capturing condition; a first-changing section to change a gradation conversion curve, which is defined for every outputting medium in advance and represents a conversion table for converting the scene-referred image data to the output-referred image data, based on the hardness adjusting value, so as to generate a first-revised gradation conversion curve; a second-changing section to change the first-revised gradation conversion curve, based on the brightness adjusting value, so as to generate a second-revised gradation conversion curve; and a generating section to generate the output-referred image data, based on the second-revised gradation conversion curve; wherein the first-changing section generates the first-revised gradation conversion curve by modifying a shape of the gradation conversion curve residing in a region other than a specific region, which serves as a fixed region including a predetermined position on the gradation conversion curve, based on the hardness adjusting value of the output-referred image data; and wherein the first-changing section generates the second-revised gradation conversion curve by modifying a shape of the first-revised gradation conversion curve in such a manner that the specific region moves on a predetermined curve defined in advance, based on the brightness adjusting value.

(32) An image-recording apparatus for generating output-referred image data by applying an optimization processing, for optimizing an output image to be formed on an outputting medium, to scene-referred image data, and then, recording the output image based on the output-referred image data onto the outputting medium, the image-recording apparatus comprising: a hardness-designating section to designate a hardness adjusting value for the output-referred image data; a first-changing section to change a gradation conversion curve, which is defined for every outputting medium in advance and represents a conversion table for converting the scene-referred image data to the output-referred image data, based on the hardness adjusting value, so as to generate a first-revised gradation conversion curve; a brightness-designating section to designate a brightness adjusting value for the output-referred image data; a second-changing section to change the first-revised gradation conversion curve, based on the brightness adjusting value, so as to generate a second-revised gradation conversion curve; and a chroma-determining section to determine a chroma adjusting value for the output-referred image data, based on the hardness adjusting value designated by the hardness-designating section; a generating section to generate the output-referred image data, based on the second-revised gradation conversion curve and the chroma adjusting value determined by the chroma-determining section; wherein the first-changing section generates the first-revised gradation conversion curve by modifying a shape of the gradation conversion curve residing in a region other than a specific region, which serves as a fixed region including a predetermined position on the gradation conversion curve, based on the hardness adjusting value of the output-referred image data; and wherein the first-changing section generates the second-revised gradation conversion curve by modifying a shape of the first-revised gradation conversion curve in such a manner that the specific region moves on a predetermined curve defined in advance, based on the brightness adjusting value.

(33) The image-recording apparatus of item 30, further comprising: a determining section to determine a hardness adjusting value and a brightness adjusting value for the output-referred image data, corresponding to a specific combination of a kind of a subject to be included in the output image and an image-capturing condition; wherein the first-changing section changes the gradation conversion curve to the first-revised gradation conversion curve, based on the hardness adjusting value determined by the determining section; and wherein the second-changing section changes the first-revised gradation conversion curve to the second-revised gradation conversion curve, based on the brightness adjusting value determined by the determining section.

(34) The image-recording apparatus of item 30, further comprising: a chroma-determining section to determine a chroma adjusting value for the output-referred image data, based on the hardness adjusting value determined by the hardness-determining section; wherein the generating section generates the output-referred image data, based on the second-revised gradation conversion curve and the chroma adjusting value determined by the chroma-determining section.

(35) The image-recording apparatus of item 31, further comprising: a chroma-determining section to determine a chroma adjusting value for the output-referred image data, based on the hardness adjusting value determined by the hardness-determining section; wherein the generating section generates the output-referred image data, based on the second-revised gradation conversion curve and the chroma adjusting value determined by the chroma-determining section.

(36) The image-recording apparatus of item 33, further comprising: a chroma-determining section to determine a chroma adjusting value for the output-referred image data, based on the hardness adjusting value determined by the hardness-determining section and the determining section; wherein the generating section generates the output-referred image data, based on the second-revised gradation conversion curve and the chroma adjusting value determined by the chroma-determining section.

(37) The image-recording apparatus of item 31, wherein the kind of subject is a portrait and the image-capturing condition is a backlight.

(38) The image-recording apparatus of item 32, wherein, when the hardness adjusting value is set at zero, the brightness adjusting value is set at such a value that chroma components of the output-referred image data are emphasized.

(39) The image-recording apparatus of item 30, wherein the kind of subject includes at least anyone of a portrait, a landscape and a still life.

(40) The image-recording apparatus of item 30, wherein the image-capturing condition includes at least anyone of a backlight and a strobe lighting.

(41) The image-processing method of item 29, wherein, when an input-output value of the gradation conversion curve is L*, the predetermined position included in the specific region is located at such a position that input value L* is smaller than 50 and equal to or greater than 40.

(42) The image-recording apparatus of item 29, further comprising: a storage section to store initial values of hardness and brightness on the gradation conversion curve, which is defined for every outputting medium in advance, while correlating them with every one of users.

(43) A computer program for executing operations for generating output-referred image data by applying an optimization processing, for optimizing an output image to be formed on an outputting medium, to scene-referred image data, the computer program comprising the functional steps of: designating a hardness adjusting value for the output-referred image data; changing a gradation conversion curve, which is defined for every outputting medium in advance and represents a conversion table for converting the scene-referred image data to the output-referred image data, based on the hardness adjusting value, so as to generate a first-revised gradation conversion curve; designating a brightness adjusting value for the output-referred image data; changing the first-revised gradation conversion curve, based on the brightness adjusting value, so as to generate a second-revised gradation conversion curve; and generating the output-referred image data, based on the second-revised gradation conversion curve; wherein the first-revised gradation conversion curve is generated by modifying a shape of the gradation conversion curve residing in a region other than a specific region, which serves as a fixed region including a predetermined position on the gradation conversion curve, based on the hardness adjusting value of the output-referred image data; and wherein the second-revised gradation conversion curve is generated by modifying a shape of the first-revised gradation conversion curve in such a manner that the specific region moves on a predetermined curve defined in advance, based on the brightness adjusting value.

(44) A computer program for executing operations for generating output-referred image data by applying an optimization processing, for optimizing an output image to be formed on an outputting medium, to scene-referred image data, the computer program comprising the functional steps of: determining a hardness adjusting value for the output-referred image data, corresponding to a kind of a subject to be included in the output image; changing a gradation conversion curve, which is defined for every outputting medium in advance and represents a conversion table for converting the scene-referred image data to the output-referred image data, based on the hardness adjusting value, so as to generate a first-revised gradation conversion curve; determining a brightness adjusting value for the output-referred image data, corresponding to an image-capturing condition; changing the first-revised gradation conversion curve, based on the brightness adjusting value, so as to generate a second-revised gradation conversion curve; and generating the output-referred image data, based on the second-revised gradation conversion curve; wherein the first-revised gradation conversion curve is generated by modifying a shape of the gradation conversion curve residing in a region other than a specific region, which serves as a fixed region including a predetermined position on the gradation conversion curve, based on the hardness adjusting value of the output-referred image data; and wherein the second-revised gradation conversion curve is generated by modifying a shape of the first-revised gradation conversion curve in such a manner that the specific region moves on a predetermined curve defined in advance, based on the brightness adjusting value.

(45) A computer program for executing operations for generating output-referred image data by applying an optimization processing, for optimizing an output image to be formed on an outputting medium, to scene-referred image data, the computer program comprising the functional steps of: determining a hardness adjusting value and a brightness adjusting value for the output-referred image data, corresponding to a specific combination of a kind of a subject to be included in the output image and an image-capturing condition; changing a gradation conversion curve, which is defined for every outputting medium in advance and represents a conversion table for converting the scene-referred image data to the output-referred image data, based on the hardness adjusting value, so as to generate a first-revised gradation conversion curve; changing the first-revised gradation conversion curve, based on the brightness adjusting value, so as to generate a second-revised gradation conversion curve; and generating the output-referred image data, based on the second-revised gradation conversion curve; wherein the first-revised gradation conversion curve is generated by modifying a shape of the gradation conversion curve residing in a region other than a specific region, which serves as a fixed region including a predetermined position on the gradation conversion curve, based on the hardness adjusting value of the output-referred image data; and wherein the second-revised gradation conversion curve is generated by modifying a shape of the first-revised gradation conversion curve in such a manner that the specific region moves on a predetermined curve defined in advance, based on the brightness adjusting value.

(46) A computer program for executing operations for generating output-referred image data by applying an optimization processing, for optimizing an output image to be formed on an outputting medium, to scene-referred image data, the computer program comprising the functional steps of: designating a hardness adjusting value for the output-referred image data; changing a gradation conversion curve, which is defined for every outputting medium in advance and represents a conversion table for converting the scene-referred image data to the output-referred image data, based on the hardness adjusting value, so as to generate a first-revised gradation conversion curve; designating a brightness adjusting value for the output-referred image data; changing the first-revised gradation conversion curve, based on the brightness adjusting value, so as to generate a second-revised gradation conversion curve; and determining a chroma adjusting value for the output-referred image data, based on the hardness adjusting value designated in the designating step; generating the output-referred image data, based on the second-revised gradation conversion curve and the chroma adjusting value determined in the determining step; wherein the first-revised gradation conversion curve is generated by modifying a shape of the gradation conversion curve residing in a region other than a specific region, which serves as a fixed region including a predetermined position on the gradation conversion curve, based on the hardness adjusting value of the output-referred image data; and wherein the second-revised gradation conversion curve is generated by modifying a shape of the first-revised gradation conversion curve in such a manner that the specific region moves on a predetermined curve defined in advance, based on the brightness adjusting value.

Further, to overcome the abovementioned problems, other image-processing methods and apparatus, and other image-recording apparatus, embodied in the present invention, will be described as follow:

(47) An image-processing method, characterized in that,
in the image-processing method for generating output-referred image data by applying an image-processing, which optimizes for a formation of a visual image on an outputting medium, to scene-referred image data, there are included,
a hardness-designating process for designating a hardness adjusting value of the output-referred image data;
a first-changing process for changing a gradation conversion curve, which is defined for every outputting medium in advance and represents a conversion from the scene-referred image data to the output-referred image data, based on the hardness adjusting value designated in the above;
a brightness-designating process for designating a brightness adjusting value of the output-referred image data;
a second-changing process for changing the gradation conversion curve, based on the brightness adjusting value designated in the above;
a generating process for generating the output-referred image data, based on the gradation conversion curve changed in the first-changing process and the second-changing process; and
in the first-changing process, setting a specific region including a predetermined position as a fixed region, a shape of the gradation conversion curve is changed, based on the hardness adjusting value, and in the second-changing process, based on the brightness adjusting value, a shape of the gradation conversion curve is changed, so that the specific region moves on a predetermined curve defined in advance.

(48) An image-processing method, characterized in that,
in the image-processing method for generating output-referred image data by applying an image-processing, which optimizes for a formation of a visual image on an outputting medium, to scene-referred image data, there are included,
a hardness-determining process for determining a hardness adjusting value of the output-referred image data, corresponding to a kind of a subject;
a first-changing process for changing a gradation conversion curve, which is defined for every outputting medium in advance and represents a conversion from the scene-referred image data to the output-referred image data, based on the hardness adjusting value determined in the above;
a brightness-determining process for determining a brightness adjusting value of the output-referred image data corresponding to an image-capturing condition;
a second-changing process for changing the gradation conversion curve, based on the brightness adjusting value determined in the above;
a generating process for generating the output-referred image data, based on the gradation conversion curve changed in the first-changing process and the second-changing process; and
in the first-changing process, setting a specific region including a predetermined position as a fixed region, a shape of the gradation conversion curve is changed, based on the hardness adjusting value, and
in the second-changing process, based on the brightness adjusting value, a shape of the gradation conversion curve is changed, so that the specific region moves on a predetermined curve defined in advance.

(49) An image-processing method, characterized in that,
in the image-processing method for generating output-referred image data by applying an image-processing, which optimizes for a formation of a visual image on an outputting medium, to scene-referred image data, there are included,
a hardness/brightness-determining process for determining a hardness adjusting value and a brightness adjusting value of the output-referred image data, corresponding to a specific combination of a kind of a subject and an image-capturing condition;
a first-changing process for changing a gradation conversion curve, which is defined for every outputting medium in advance and represents a conversion from the scene-referred image data to the output-referred image data, based on the hardness adjusting value determined in the above;
a second-changing process for changing the gradation conversion curve, based on the brightness adjusting value determined in the above;
a generating process for generating the output-referred image data, based on the gradation conversion curve changed in the first-changing process and the second-changing process; and
in the first-changing process, setting a specific region including a predetermined position as a fixed region, a shape of the gradation conversion curve is changed, based on the hardness adjusting value, and
in the second-changing process, based on the brightness adjusting value, a shape of the gradation conversion curve is changed, so that the specific region moves on a predetermined curve defined in advance.

(50) An image-processing method, characterized in that,
in the image-processing method for generating output-referred image data by applying an image-processing, which optimizes for a formation of a visual image on an outputting medium, to scene-referred image data, there are included,
a hardness-designating process for designating a hardness adjusting value of the output-referred image data;
a first-changing process for changing a gradation conversion curve, which is defined for every outputting medium in advance and represents a conversion from the scene-referred image data to the output-referred image data, based on the hardness adjusting value designated in the above;
a brightness-designating process for designating a brightness adjusting value of the output-referred image data;
a second-changing process for changing the gradation conversion curve, based on the brightness adjusting value designated in the above;
a chroma-determining process for determining a chroma adjusting value of the output-referred image data, based on the hardness adjusting value designated in the above;
a generating process for generating the output-referred image data, based on the gradation conversion curve changed in the first-changing process and the second-changing process; and
in the first-changing process, setting a specific region including a predetermined position as a fixed region, a shape of the gradation conversion curve is changed, based on the hardness adjusting value, and in the second-changing process, based on the brightness adjusting value, a shape of the gradation conversion curve is changed, so that the specific region moves on a predetermined curve defined in advance.

(51) The image-processing method, described in item 48, characterized in that there are further included
a hardness/brightness-determining process for determining a hardness adjusting value and a brightness adjusting value of the output-referred image data, corresponding to a specific combination of a kind of a subject and an image-capturing condition, and
in the first-changing process, the gradation conversion curve is changed, based on the hardness adjusting value determined in the hardness-determining process and the hardness/brightness-determining process, and
in the second-changing process, the gradation conversion curve is changed, based on the brightness adjusting value determined in the brightness-determining process and the hardness/brightness-determining process.

(52) The image-processing method, described in item 48, characterized in that there are further included
a chroma-determining process for determining a chroma adjusting value of the output-referred image data, based on the hardness adjusting value determined in the hardness-determining process, and
in the generating process, the output-referred image data are generated, based on the gradation conversion curve changed in the first-changing process and the second-changing process, and based on the chroma adjusting value.

(53) The image-processing method, described in item 49, characterized in that there are further included
a chroma-determining process for determining a chroma adjusting value of the output-referred image data, based on the hardness adjusting value determined in the hardness-determining process, and
in the generating process, the output-referred image data are generated, based on the gradation conversion curve changed in the first-changing process and the second-changing process, and based on the chroma adjusting value.

(54) The image-processing method, described in item 51, characterized in that there are further included
a chroma-determining process for determining a chroma adjusting value of the output-referred image data, based on the hardness adjusting value determined in the hardness-determining process and the hardness/brightness-determining process, and
in the generating process, the output-referred image data are generated, based on the gradation conversion curve changed in the first-changing process and the second-changing process, and based on the chroma adjusting value.

(55) The image-processing method, described in anyone of items 49, 51, 53 and 54, characterized in that,
in the specific combination of said kind of subject and the image-capturing condition, the kind of subject is a portrait and the image-capturing condition is a backlight.

(56) The image-processing method, described in anyone of items 50 and 52-54, characterized in that,
when the hardness adjusting value is zero, the brightness adjusting value is such a value that chroma of the output-referred image data is emphasized.

(57) The image-processing method, described in anyone of items 48, 49 and 51-56, characterized in that,
the kind of subject includes at least anyone of a portrait, a landscape and a still life.

(58) The image-processing method, described in anyone of items 48, 49 and 51-57, characterized in that,
the image-capturing condition includes at least anyone of a backlight and a strobe photographing.

(59) The image-processing method, described in anyone of items 47-58, characterized in that,
when an input-output value of the gradation conversion curve is L*, the predetermined position included in the specific region is located at such a position that input value L* is smaller than 50 and equal to or greater than 40.

(60) The image-processing method, described in anyone of items 47-59, characterized in that,
initial values of hardness and brightness on the gradation conversion curve, which is defined for every outputting medium in advance, are stored in a storage by users.

(61) An image-processing apparatus, characterized in that,
in the image-processing apparatus for generating output-referred image data by applying an image-processing, which optimizes for a formation of a visual image on an outputting medium, to scene-referred image data, there are included,
a hardness-designating section for designating a hardness adjusting value of the output-referred image data;
a first-changing section for changing a gradation conversion curve, which is defined for every outputting medium in advance and represents a conversion from the scene-referred image data to the output-referred image data, based on the hardness adjusting value designated in the above;
a brightness-designating section for designating a brightness adjusting value of the output-referred image data;
a second-changing section for changing the gradation conversion curve, based on the brightness adjusting value designated in the above;
a generating section for generating the output-referred image data, based on the gradation conversion curve changed in the first-changing section and the second-changing section; and
setting a specific region including a predetermined position as a fixed region, the first-changing section changes a shape of the gradation conversion curve, based on the hardness adjusting value, and
based on the brightness adjusting value, the second-changing section changes a shape of the gradation conversion curve, so that the specific region moves on a predetermined curve defined in advance.

(62) An image-processing apparatus, characterized in that,
in the image-processing apparatus for generating output-referred image data by applying an image-processing, which optimizes for a formation of a visual image on an outputting medium, to scene-referred image data, there are included,
a hardness-determining section for determining a hardness adjusting value of the output-referred image data, corresponding to a kind of a subject;
a first-changing section for changing a gradation conversion curve, which is defined for every outputting medium in advance and represents a conversion from the scene-referred image data to the output-referred image data, based on the hardness adjusting value determined in the above;
a brightness-determining section for determining a brightness adjusting value of the output-referred image data corresponding to an image-capturing condition;
a second-changing section for changing the gradation conversion curve, based on the brightness adjusting value determined in the above;
a generating section for generating the output-referred image data, based on the gradation conversion curve changed in the first-changing section and the second-changing section; and
setting a specific region including a predetermined position as a fixed region, the first-changing section changes a shape of the gradation conversion curve, based on the hardness adjusting value, and
based on the brightness adjusting value, the second-changing section changes a shape of the gradation conversion curve, so that the specific region moves on a predetermined curve defined in advance.

(63) An image-processing apparatus, characterized in that,
in the image-processing apparatus for generating output-referred image data by applying an image-processing, which optimizes for a formation of a visual image on an outputting medium, to scene-referred image data, there are included,
a hardness/brightness-determining section for determining a hardness adjusting value and a brightness adjusting value of the output-referred image data, corresponding to a specific combination of a kind of a subject and an image-capturing condition;
a first-changing section for changing a gradation conversion curve, which is defined for every outputting medium in advance and represents a conversion from the scene-referred image data to the output-referred image data, based on the hardness adjusting value determined in the above;
a second-changing section for changing the gradation conversion curve, based on the brightness adjusting value determined in the above;
a generating section for generating the output-referred image data, based on the gradation conversion curve changed in the first-changing section and the second-changing section; and
setting a specific region including a predetermined position as a fixed region, the first-changing section changes a shape of the gradation conversion curve, based on the hardness adjusting value, and
based on the brightness adjusting value, the second-changing section changes a shape of the gradation conversion curve, so that the specific region moves on a predetermined curve defined in advance.

(64) An image-processing apparatus, characterized in that,
in the image-processing apparatus for generating output-referred image data by applying an image-processing, which optimizes for a formation of a visual image on an outputting medium, to scene-referred image data, there are included,
a hardness-designating section for designating a hardness adjusting value of the output-referred image data;
a first-changing section for changing a gradation conversion curve, which is defined for every outputting medium in advance and represents a conversion from the scene-referred image data to the output-referred image data, based on the hardness adjusting value designated in the above;
a brightness-designating section for designating a brightness adjusting value of the output-referred image data;
a second-changing section for changing the gradation conversion curve, based on the brightness adjusting value designated in the above;
a chroma-determining section for determining a chroma adjusting value of the output-referred image data, based on the hardness adjusting value designated in the above;
a generating section for generating the output-referred image data, based on the gradation conversion curve changed in the first-changing section and the second-changing section; and
setting a specific region including a predetermined position as a fixed region, the first-changing section changes a shape of the gradation conversion curve, based on the hardness adjusting value, and
based on the brightness adjusting value, the second-changing section changes a shape of the gradation conversion curve, so that the specific region moves on a predetermined curve defined in advance.

(65) The image-processing apparatus, described in item 62, characterized in that there are further included
a hardness/brightness-determining section for determining a hardness adjusting value and a brightness adjusting value of the output-referred image data, corresponding to a specific combination of a kind of a subject and an image-capturing condition, and
the first-changing section changes the gradation conversion curve, based on the hardness adjusting value determined in the hardness-determining section and the hardness/brightness-determining section, and
the second-changing section changes the gradation conversion curve, based on the brightness adjusting value determined in the brightness-determining section and the hardness/brightness-determining section.

(66) The image-processing apparatus, described in item 62, characterized in that there are further included
a chroma-determining section for determining a chroma adjusting value of the output-referred image data, based on the hardness adjusting value determined in the hardness-determining section, and
the generating section generates the output-referred image data, based on the gradation conversion curve changed in the first-changing section and the second-changing section, and based on the chroma adjusting value.

(67) The image-processing apparatus, described in item 63, characterized in that there are further included
a chroma-determining section for determining a chroma adjusting value of the output-referred image data, based on the hardness adjusting value determined in the above, and
the generating section generates the output-referred image data, based on the gradation conversion curve changed in the first-changing section and the second-changing section, and based on the chroma adjusting value.

(68) The image-processing apparatus, described in item 65, characterized in that there are further included
a chroma-determining section for determining a chroma adjusting value of the output-referred image data, based on the hardness adjusting value determined by the hardness-determining section and the hardness/brightness-determining section, and
the generating section generates the output-referred image data, based on the gradation conversion curve changed by the first-changing section and the second-changing section, and based on the chroma adjusting value.

(69) The image-processing apparatus, described in anyone of items 63, 65, 67 and 68, characterized in that,
in the specific combination of said kind of subject and the image-capturing condition, the kind of subject is a portrait and the image-capturing condition is a backlight.

(70) The image-processing apparatus, described in anyone of items 64 and 66-68, characterized in that,
when the hardness adjusting value is zero, the brightness adjusting value is such a value that chroma of the output-referred image data is emphasized.

(71) The image-processing apparatus, described in anyone of items 62, 63 and 65-70, characterized in that,
the kind of subject includes at least anyone of a portrait, a landscape and a still life.

(72) The image-processing apparatus, described in anyone of items 62, 63 and 65-71, characterized in that,
the image-capturing condition includes at least anyone of a backlight and a strobe photographing.

(73) The image-processing apparatus, described in anyone of items 61-72, characterized in that,
when an input-output value of the gradation conversion curve is L*, the predetermined position included in the specific region is located at such a position that input value L* is smaller than 50 and equal to or greater than 40.

(74) The image-processing apparatus, described in anyone of items 61-73, characterized in that,
initial values of hardness and brightness on the gradation conversion curve, which is defined for every outputting medium in advance, are stored in a storage by users.

(75) An image-recording apparatus, characterized in that,
in the image-recording apparatus for generating output-referred image data by applying an image-processing, which optimizes for a formation of a visual image on an outputting medium, to scene-referred image data, and then, forming the generated output-referred image data onto the outputting medium,
a hardness-designating section for designating a hardness adjusting value of the output-referred image data;
a first-changing section for changing a gradation conversion curve, which is defined for every outputting medium in advance and represents a conversion from the scene-referred image data to the output-referred image data, based on the hardness adjusting value designated in the above;
a brightness-designating section for designating a brightness adjusting value of the output-referred image data;
a second-changing section for changing the gradation conversion curve, based on the brightness adjusting value designated in the above;
a generating section for generating the output-referred image data, based on the gradation conversion curve changed in the first-changing section and the second-changing section; and
setting a specific region including a predetermined position as a fixed region, the first-changing section changes a shape of the gradation conversion curve, based on the hardness adjusting value, and
based on the brightness adjusting value, the second-changing section changes a shape of the gradation conversion curve, so that the specific region moves on a predetermined curve defined in advance.

(76) An image-recording apparatus, characterized in that,
in the image-recording apparatus for generating output-referred image data by applying an image-processing, which optimizes for a formation of a visual image on an outputting medium, to scene-referred image data, and then, forming the generated output-referred image data onto the outputting medium, there are included,
a hardness-determining section for determining a hardness adjusting value of the output-referred image data, corresponding to a kind of a subject;
a first-changing section for changing a gradation conversion curve, which is defined for every outputting medium in advance and represents a conversion from the scene-referred image data to the output-referred image data, based on the hardness adjusting value determined in the above;
a brightness-determining section for determining a brightness adjusting value of the output-referred image data corresponding to an image-capturing condition;
a second-changing section for changing the gradation conversion curve, based on the brightness adjusting value determined in the above;
a generating section for generating the output-referred image data, based on the gradation conversion curve changed in the first-changing section and the second-changing section; and
setting a specific region including a predetermined position as a fixed region, the first-changing section changes a shape of the gradation conversion curve, based on the hardness adjusting value, and
based on the brightness adjusting value, the second-changing section changes a shape of the gradation conversion curve, so that the specific region moves on a predetermined curve defined in advance.

(77) An image-recording apparatus, characterized in that,
in the image-recording apparatus for generating output-referred image data by applying an image-processing, which optimizes for a formation of a visual image on an outputting medium, to scene-referred image data, and then, forming the generated output-referred image data onto the outputting medium, there are included,
a hardness/brightness-determining section for determining a hardness adjusting value and a brightness adjusting value of the output-referred image data, corresponding to a specific combination of a kind of a subject and an image-capturing condition;
a first-changing section for changing a gradation conversion curve, which is defined for every outputting medium in advance and represents a conversion from the scene-referred image data to the output-referred image data, based on the hardness adjusting value determined in the above;
a second-changing section for changing the gradation conversion curve, based on the brightness adjusting value determined in the above;
a generating section for generating the output-referred image data, based on the gradation conversion curve changed in the first-changing section and the second-changing section; and
setting a specific region including a predetermined position as a fixed region, the first-changing section changes a shape of the gradation conversion curve, based on the hardness adjusting value, and
based on the brightness adjusting value, the second-changing section changes a shape of the gradation conversion curve, so that the specific region moves on a predetermined curve defined in advance.

(78) An image-recording apparatus, characterized in that,
in the image-recording apparatus for generating output-referred image data by applying an image-processing, which optimizes for a formation of a visual image on an outputting medium, to scene-referred image data, and then, forming the generated output-referred image data onto the outputting medium, there are included,
a hardness-designating section for designating a hardness adjusting value of the output-referred image data;
a first-changing section for changing a gradation conversion curve, which is defined for every outputting medium in advance and represents a conversion from the scene-referred image data to the output-referred image data, based on the hardness adjusting value designated in the above;
a brightness-designating section for designating a brightness adjusting value of the output-referred image data;
a second-changing section for changing the gradation conversion curve, based on the brightness adjusting value designated in the above;
a chroma-determining section for determining a chroma adjusting value of the output-referred image data, based on the hardness adjusting value designated in the above;
a generating section for generating the output-referred image data, based on the gradation conversion curve changed in the first-changing section and the second-changing section; and
setting a specific region including a predetermined position as a fixed region, the first-changing section changes a shape of the gradation conversion curve, based on the hardness adjusting value, and
based on the brightness adjusting value, the second-changing section changes a shape of the gradation conversion curve, so that the specific region moves on a predetermined curve defined in advance.

(79) The image-recording apparatus, described in item 76, characterized in that there are further included
a hardness/brightness-determining section for determining a hardness adjusting value and a brightness adjusting value of the output-referred image data, corresponding to a specific combination of a kind of a subject and an image-capturing condition, and
the first-changing section changes the gradation conversion curve, based on the hardness adjusting value determined in the hardness-determining section and the hardness/brightness-determining section, and
the second-changing section changes the gradation conversion curve, based on the brightness adjusting value determined in the brightness-determining section and the hardness/brightness-determining section.

(80) The image-recording apparatus, described in item 76, characterized in that there are further included
a chroma-determining section for determining a chroma adjusting value of the output-referred image data, based on the hardness adjusting value determined in the hardness-determining section, and
the generating section generates the output-referred image data, based on the gradation conversion curve changed in the first-changing section and the second-changing section, and based on the chroma adjusting value.

(81) The image-recording apparatus, described in item 77, characterized in that there are further included
a chroma-determining section for determining a chroma adjusting value of the output-referred image data, based on the hardness adjusting value determined in the above, and
the generating section generates the output-referred image data, based on the gradation conversion curve changed in the first-changing section and the second-changing section, and based on the chroma adjusting value.

(82) The image-recording apparatus, described in item 79, characterized in that there are further included
a chroma-determining section for determining a chroma adjusting value of the output-referred image data, based on the hardness adjusting value determined by the hardness-determining section and the hardness/brightness-determining section, and
the generating section generates the output-referred image data, based on the gradation conversion curve changed by the first-changing section and the second-changing section, and based on the chroma adjusting value.

(83) The image-recording apparatus, described in anyone of items 77, 79, 81 and 82, characterized in that,
in the specific combination of said kind of subject and the image-capturing condition, the kind of subject is a portrait and the image-capturing condition is a backlight.

(84) The image-recording apparatus, described in anyone of items 78 and 80-82, characterized in that,
when the hardness adjusting value is zero, the brightness adjusting value is such a value that chroma of the output-referred image data is emphasized.

(85) The image-recording apparatus, described in anyone of items 76, 77 and 79-84, characterized in that,
the kind of subject includes at least anyone of a portrait, a landscape and a still life.

(86) The image-recording apparatus, described in anyone of items 76, 77 and 79-85, characterized in that,
the image-capturing condition includes at least anyone of a backlight and a strobe photographing.

(87) The image-recording apparatus, described in anyone of items 75-86, characterized in that,
when an input-output value of the gradation conversion curve is L*, the predetermined position included in the specific region is located at such a position that input value L* is smaller than 50 and equal to or greater than 40.

(88) The image-recording apparatus, described in anyone of items 75-87, characterized in that,
initial values of hardness and brightness on the gradation conversion curve, which is defined for every outputting medium in advance, are stored in a storage by users.

In the present invention, a specific region including a predetermined position on a gradation conversion curve representing the conversion from the scene-referred image data to the output-referred image is assumed as an fixed region, and the shape of the gradation conversion curve is changed, thereby adjusting the hardness of the output-referred image, and changing the shape of the gradation conversion curve in such a way that the specific region will move along the pre-defined curve. Through these steps, the brightness of the output-referred image data is adjusted, whereby the efficiency in the setting of the gradation conversion curve can be improved. This allows the adjustment of the brightness of the output-referred image whose fluctuation in hardness is reduced.

The efficiency in the setting of the gradation conversion curve can be improved by adjusting the hardness of the output-referred image data in response to the category of a subject and adjusting the brightness of the output-referred image data in response to photographic conditions. Further improvement of the efficiency in the setting of the gradation conversion curve can be achieved by adjusting the hardness and brightness of the output-referred image data in response to the combination of the category of a specific subject and photographic conditions.

In response to the adjustment value of the hardness of the output-referred image data, the chroma of the output-referred image data can be adjusted. This arrangement not only improves the efficiency in the setting of the gradation conversion curve but also provides preferable output-referred image data.

The following describes the details of the terminology used in the present invention:

The term “generate” appearing in the description of the present Specification refers to the act of a new image signal or data being produced by a program and processing circuit working in the image processing methods and apparatus, and image recording apparatus according to the present invention. The term “create” may be used synonymously with it.

The term “scene-referred image data” used in the specification of the present application refers to the image data obtained by applying processing of mapping the signal intensity of each color channel based on at least the spectral sensitivity of the image sensor itself to the standard color space such as the aforementioned, RIMM RGB and ERIMM RGB. The term signifies the image data where image processing of modifying the data contents as to improve the effect of viewing the image such as gradation conversion, sharpness enhancement and color saturation enhancement is omitted. It is preferred that the scene-referred raw data be subjected to correction (opto-electronic conversion function defined in ISO1452, e.g. “Fine imaging and digital photographing” edited by the Publishing Commission of the Japan Society of Electrophotography, Corona Publishing Co., P. 449) of the photoelectric conversion characteristics of the image-capturing apparatus. It is preferred that the amount of the scene-referred image data of a standardized form (e.g. number of gradations) be equal to or greater than the amount of information (e.g. the number of gradations) required by the output-referred image data (to be described later) according to the performance of the aforementioned analog-to-digital converter. For example, when the number of gradations of the output-referred image data is 8 bits per channel, the number of gradations of the scene-referred image data should preferably be 12 bits or more, and more preferably 16 bits or more.

The “output-referred image data” (also referred to as “visual image referred image data”) denotes digital image data that is used by such a display device as CRT, liquid crystal display and plasma display, or by the output device for generation of a hard copy image on such an outputting medium as silver halide photographic paper, inkjet paper and thermal printing paper. The output-referred image data is provided with “optimization processing” in order to obtain the optimum image on such a display device as CRT, liquid crystal display and plasma display, or such an outputting medium as silver halide photographic paper, inkjet paper and thermal printing paper.

The “Optimization processing” is provided to ensure the optimum image on such display device as CRT, liquid crystal display and plasma display, or such an outputting medium as silver halide photographic paper, inkjet paper and thermal printing paper. For example, when display is given on the CRT display monitor conforming to the sRGB standard, processing is provided in such a way that the optimum color reproduction can be gained within the color gamut of the sRGB standard. When the data is to be outputted on silver halide photographic paper, processing is provided in such a way that the optimum color reproduction can be gained within the color gamut of silver halide photographic paper. In addition to compression of the above-mentioned color gamut, compression of gradation from 16 to 8 bits, reduction in the number of output pixels, and processing in response to the output characteristics (LUT) of the output device are also included. Further, it goes without saying that such processing as noise control, sharpening, white balance adjustment, color saturation adjustment or dodging is carried out.

The “outputting medium” appearing in the present invention is defined as including such a display device as CRT, liquid crystal display and plasma display, or such paper for generation of a hard copy image as silver halide photographic paper, inkjet paper and thermal printing paper.

The “gradation conversion curve” is defined as an input/output conversion curve (“Look Up Table; hereinafter referred to as “LUT” for simplicity) for conversion of “scene-referred image data” into “output-referred image data”. It is a curve on a graph with input L* plotted on the horizontal axis, and output L* plotted on the vertical axis, as shown in FIG. 1. In FIG. 1, input L* denotes the brightness (luminance) of the subject, and is proportional to the linear portion of the CCD output. The output L* denotes the result of gradation conversion, using a value obtained from a predetermined brightness (luminance) calculation formula, when the input L* is mapped into an sRGB color space.

Further, the “gradation conversion curve for conversion from scene-referred image data to output-referred image data defined for each output medium” means that a “gradation conversion curve” is prepared for each type of a display device such as a CRT, liquid crystal display and plasma display, and paper such as silver halide photographic paper, inkjet paper and thermal printer paper.

The “specific region containing a predetermined position on the gradation conversion curve” denotes a predetermined region including a point on the gradation conversion curve for conversion of scene-referred image data to output-referred image data, as shown in FIG. 2. Here “a predetermined position” is preferred to be such that the input L* is located at the position 40 or more to 50 exclusive, as described in claims 13, 27 and 41.

The relationship among “a predetermined region”, “a specific region” and “a predetermined position” depends on the relational expression for changing the shape of the gradation conversion curve. When defining the relational expression for changing the shape of the gradation conversion curve, using the “hardness adjusting value” (hardness adjusting parameter) inputted by the user, it is preferred that “a predetermined position” occupy the center of “a special region” so that the range of the specific region will be minimized. It is particularly preferred that the range of the specific region do not exceed δ 10 in terms of input/output L*. It is still more preferred that this range do not exceed δ 5. In this case, the number of hardness adjusting parameters should preferably be one.

“A specific region is assumed as an fixed region, and the shape of the gradation conversion curve is changed based on the aforementioned hardness adjusting value” means that the input/output value is fixed for at least one point on the gradation conversion curve within the specific region, as shown in FIG. 2, and the hardness is adjusted, thereby reproducing the shape of an S-shaped curve. When the hardness has been set to a higher level, there is an increase in the inclination at the point, on the gradation conversion curve, passing through the specific region. Numeral 1 in FIG. 2 denotes “a predetermined position”, and 2 “a specified position”. In the present invention, it is preferred that the output value of the input L*=0 in FIG. 2 be fixed at 1*=0, and the output value of the input L*=100 be fixed at L*=100. Setting the fixed region in this manner enables hardness adjustment of the output-referred image data with reduced fluctuation in brightness.

The “shape of the gradation conversion curve is changed, . . . in such a way that the specific region will move along the pre-defined curve” is intended to set the shape of the gradation conversion curve in such a way that the specific region is always located on a predetermined parabolic traveling locus, even when the brightness is changed, as shown in FIG. 3. Numeral 4 in FIG. 3 denotes the “predetermined position” in the initial status prior to adjustment of brightness, numeral 3 denotes the “predetermined position” when brightness is adjusted to a brighter level and numeral 5 indicates the “predetermined position” when brightness is adjusted to a less bright level.

When defining the relational expression for changing the shape of the gradation conversion curve using the “brightness adjusting value” (brightness adjusting parameter) inputted by a user, it is preferred to ensure that displacement from the traveling locus is minimized. In the present invention, it is preferred that the output value of the input L*=0 in FIG. 3 be fixed at L*=0, and the output value of the input L*=100 be fixed at L*=100. The number of the brightness adjusting parameters is preferred to be one. Setting the moving locus in this manner enables brightness adjustment of the output-referred image data with reduced fluctuation in hardness.

“To determine the hardness adjusting value of the output-referred image data in response to the category of a subject” is to make adjustment to get the level of hardness differing for each category of the subject. To put it more specifically, it refers to the step of presetting the numeral different for each category of the subject and adjusting the hardness according to automatic identification or the category information of the subject (major subject) inputted manually by an operator. This is based on the finding, obtained from a survey on hardness adjusting factors, that the hardness is often adjusted according to the difference in such a subject category as a portrait and outdoor scene. In the present invention, the subject category is preferred to include the portrait, landscape and still life, as described in claims 11, 25 and 39.

The “subject category” described in the present invention denotes a category of the subject intentionally photographed by a photographer. The “portrait” in the present invention refers to the subject where the area occupied by the face accounts for 20% or more of the entire picture. The “landscape” in the present invention is defined as the scene photographed outdoors, and refers to such a natural subject as sky, verdure of trees and mountains. The “still life” in the present invention denotes the subject where the area occupied by other than living things accounts for 50% or more of the entire picture.

“To determine the bright adjusting value of the output-referred image data in response to photographic conditions” is to make adjustment to get the level of brightness differing for each photographic condition. To put it more specifically, it refers to the step of presetting the numeral different for each photographic condition and adjusting the brightness according to automatic identification or the category information of the photographic conditions inputted manually by an operator. This is based on the finding, obtained from a survey on brightness adjusting factors, that the brightness is often adjusted according to the difference in such a photographic condition as a flash mode and backlight. In the present invention, the photographic conditions are preferred to include a flash mode and backlight, as described in claims 12, 16 and 40. Thus, the efficiency in the step of changing the gradation conversion curve can be improved by adjusting the hardness of the output-referred image data in response to the category of a subject and adjusting the brightness of the output-referred image data in response to photographic conditions.

The “photographic conditions” described in the present invention mainly refers to the conditions on the light source at the time of photographing. The term “backlight” used in the description of the present invention refers to the photographic conditions where the sun is positioned within 45 degrees on the right and left with respect to the front surface of the photographer on a fine day. The term “flash mode” appearing in the description of the present invention indicates the photographic condition where a photograph is taken in a flash mode.

“To determine the brightness adjusting value and hardness adjusting value of the output-referred image data in response to the combination of the category of a specific subject and photographic conditions” is to follow the steps of presetting the combination of the category of a specific subject and photographic conditions, and applying the processing of hardness and brightness adjustment under special conditions to the photographic image data corresponding to this combination. This is based on the finding that extremely large hardness adjusting value and brightness are present in the combination of the specific subject and photographic conditions, wherein this finding was obtained in the visual experiment when a survey was made on the aforementioned factor affecting the adjustment of hardness and brightness.

“To determine the amount of adjusting the chroma of output-referred image data based on the hardness adjusting value” is to follow the step of defining the relational expression in advance so that the amount (%) of chroma adjustment can be determined in response to hardness adjusting value. This is based on the finding that hardness adjusting value and the amount of chroma adjustment are correlated with each other, wherein this finding was obtained in the visual experiment when a survey was made on the aforementioned factor affecting the adjustment of hardness and brightness. It has also been found out that the chroma adjustment of +10% occurs most frequently when the hardness adjusting value of output-referred image data is 0. Thus, as described in claims 10, 24 and 38, when the hardness adjusting value is 0, the amount of chroma adjustment should preferably be set by processing of chroma enhancement.

The image recording apparatus of the present invention can be equipped with a film scanner for inputting the frame image information of the photosensitive material recorded by an analog camera including a color film, color reversal film, black-and-white negative and black-and-white reversal film, or a flat head scanner for inputting the image information reproduced on color paper as silver halide photographic paper, in addition to the mechanism of applying image processing of the present invention to the digital image data obtained by the image-capturing apparatus of the present invention. It can be equipped with means for reading digital image data stored in the known portable “medium” including a compact flash (registered trademark), memory stick, smart media, multi-media card, floppy (registered trademark) disk, magneto-optics storage medium (MO) or CD-R. Alternatively, it can be equipped with processing means for forming an output-referred image on a display device such as a CRT, liquid crystal display and plasma display, and a storage medium of any known type including silver halide photographic paper, inkjet paper and thermal printing paper, by obtaining digital image data from a remote place through communications means such as the Internet.

### BRIEF DESCRIPTION OF THE DRAWINGS

Other objects and advantages of the present invention will become apparent upon reading the following detailed description and upon reference to the drawings in which:

FIG. 1 is a diagram representing the gradation conversion curve for converting scene-referred image data to output-referred image data;

FIG. 2 is a diagram representing a predetermined position 1 on the gradation conversion curve in FIG. 1 and a specific position 2 including this predetermined position 1;

FIG. 3 is a diagram representing the traveling locus of the specific position 2;

FIG. 4 is a perspective view showing the external configuration of an image recording apparatus 1 as an embodiment of the present invention;

FIG. 5 is block diagram showing the internal configuration of an image recording apparatus 1;

FIG. 6 is block diagram showing the functional configuration of an image processing section 70 in the first embodiment of the present invention;

FIG. 7 is block diagram showing the functional configuration of an image processing apparatus 115 in the first embodiment of the present invention;

FIG. 8 is a diagram showing an example of the gradation conversion curve;

FIG. 9 is a diagram showing an example of the gradation conversion curve;

FIG. 10 is a diagram showing an example of the traveling locus of a specific region (fixed region) in the gradation conversion curve;

FIG. 11 is a flowchart representing image processing in the first embodiment;

FIG. 12 is block diagram showing the functional configuration of an image processing section 70 in the second embodiment of the present invention;

FIG. 13 is block diagram showing the functional configuration of an image processing apparatus 115 in the second embodiment of the present invention;

FIG. 14 is a flowchart, which represents image processing in the second embodiment;

FIG. 15 is a block diagram showing the functional configuration of an image processing section 70 in the third embodiment of the present invention;

FIG. 16 is a block diagram showing the functional configuration of an image processing apparatus 115 in the third embodiment of the present invention;

FIG. 17 is a flowchart, which represents image processing in the third embodiment;

FIG. 18 is block diagram showing the functional configuration of an image processing section 70 in the fourth embodiment of the present invention;

FIG. 19 is block diagram showing the functional configuration of an image processing apparatus 115 in the fourth embodiment of the present invention;

FIG. 20 is a diagram showing the relationship between the difference DG (&y) from the initial gradation conversion curve for hardness (L* 25 through 75) and the amount of chroma adjustment PS (%); and

FIG. 21 is a fluorescent representing image processing in the fourth embodiment.

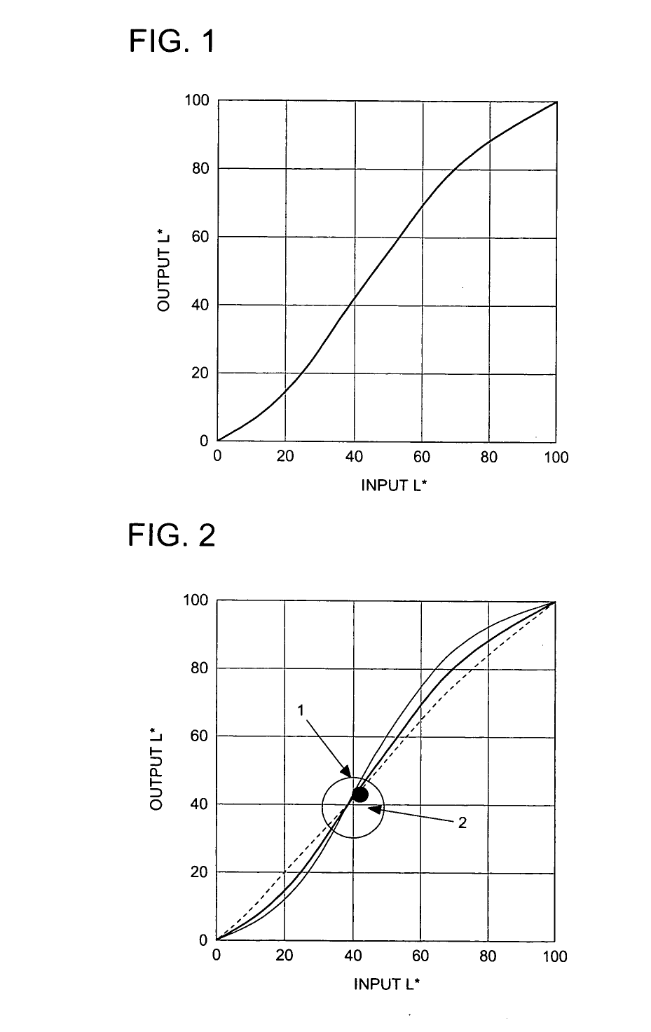

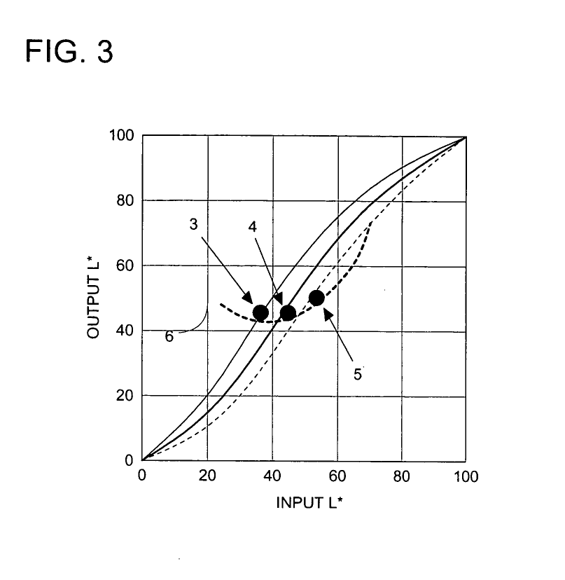

### DETAILED DESCRIPTION OF THE PREFERRED EMBODIMENT

Referring to the drawings, the embodiment of the present invention will be detailed in the following.

Outlook Structure of Image-Recording Apparatus 1

Initially, the configuration of image-recording apparatus 1 will be detailed in the following.

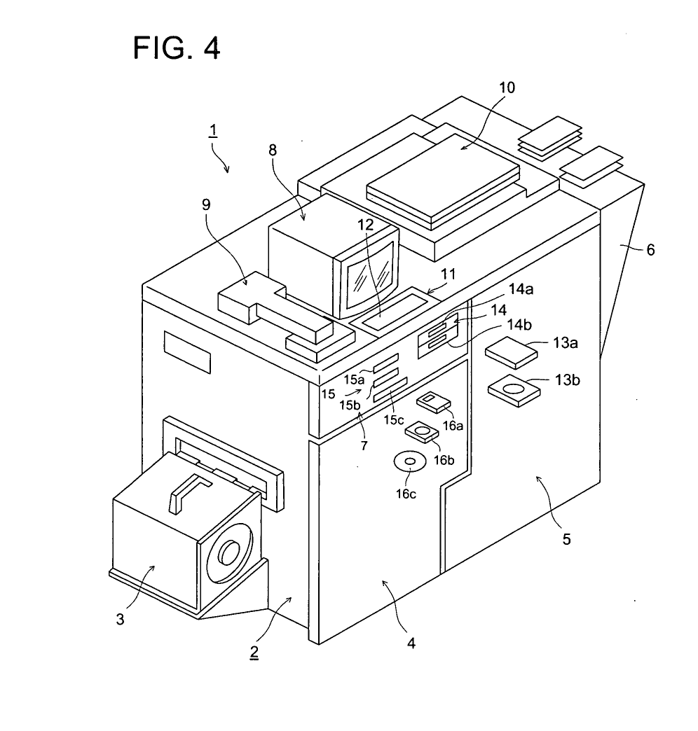

FIG. 4 shows a perspective view of the outlook structure of image-recording apparatus 1 embodied in the present invention. As shown in FIG. 4, image-recording apparatus 1 is provided with magazine loading section 3 mounted on a side of housing body 2, exposure processing section 4, for exposing a photosensitive material, mounted inside housing body 2 and print creating section 5 for creating a print. Further, tray 6 for receiving ejected prints is installed on another side of housing body 2.

Still further, CRT 8 (Cathode Ray Tube 8) serving as a display device, film scanning section 9 serving as a device for reading a transparent document, reflected document input section 10 and operating section 11 are provided on the upper side of housing body 2. CRT 8 serves as the display device for displaying the image represented by the image information to be created as the print. Further, image reading section 14 capable of reading image information recorded in various kinds of digital recording mediums and image writing section 15 capable of writing (outputting) image signals onto various kinds of digital recording mediums are provided in housing body 2. Still further, control section 7 for centrally controlling the abovementioned sections is also provided in housing body 2.

Image reading section 14 is provided with PC card adaptor 14a, floppy (Registered Trade Mark) disc adaptor 14b, into each of which PC card 13a and floppy disc 13b can be respectively inserted. For instance, PC card 13a has a storage for storing the information with respect to a plurality of frame images captured by the digital still camera. Further, for instance, a plurality of frame images captured by the digital still camera are stored in floppy disc 13b. Other than PC card 13a and floppy (Registered Trade Mark) disc 13b, a multimedia card (Registered Trade Mark), a memory stick (Registered Trade Mark), MD data, CD-ROM, etc., can be cited as recording media in which frame image data can be stored.

Image writing section 15 is provided with floppy (Registered Trade Mark) disk adaptor 15a, MO adaptor 15b and optical disk adaptor 15c, into each of which FD 16a, MO 16b and optical disc 16c can be respectively inserted. Further, CD-R, DVD-R, etc. can be cited as optical disc 16c.

Incidentally, although, in the configuration shown in FIG. 4, operating section 11, CRT 8, film scanning section 9, reflected document input section 10 and image reading section 14 are integrally provided in housing body 2, it is also applicable that one or more of them is separately disposed outside housing body 2.

Further, although image-recording apparatus 1, which creates a print by exposing/developing the photosensitive material, is exemplified in FIG. 4, the scope of the print creating method in the present invention is not limited to the above, but an apparatus employing any kind of methods, including, for instance, an ink-jetting method, an electro-photographic method, a heat-sensitive method and a sublimation method, is also applicable in the present invention.

Internal Configuration of Image-Recording Apparatus 1

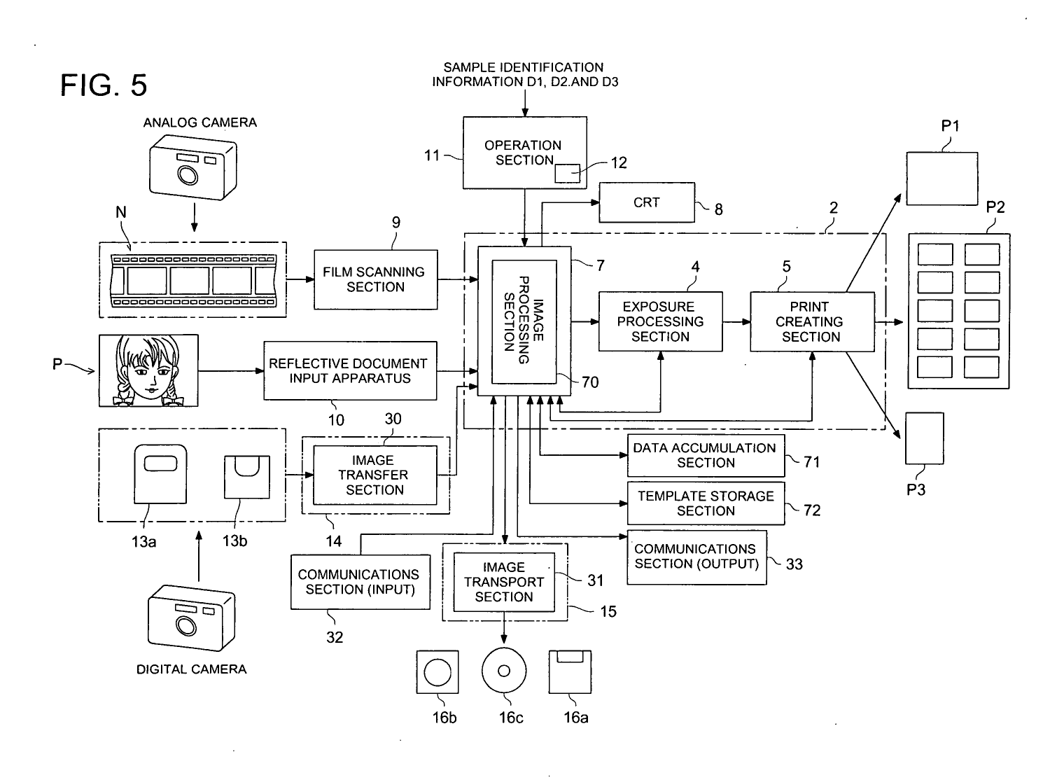

FIG. 5 shows a block diagram of the internal configuration of image-recording apparatus 1. As shown in FIG. 5, control section 7, exposure processing section 4, print creating section 5, film scanning section 9, reflected document input section 10, image reading section 14, communicating section 32 (input), image writing section 15, data storage section 71, operating section 11, CRT 8 and communicating section 33 (output) constitute image-recording apparatus 1.

Control section 7 includes a microcomputer to control the various sections constituting image-recording apparatus 1 by cooperative operations of CPU (Central Processing Unit) (not shown in the drawings) and various kinds of controlling programs, including an image-processing program, etc., stored in a storage section (not shown in the drawings), such as ROM (Read Only Memory), etc.

Further, control section 7 is provided with image-processing section 70, relating to the image-processing apparatus embodied in the present invention, which applies the image processing of the present invention to image data acquired from film scanning section 9 and reflected document input section 10, image data read from image reading section 14 and image data inputted from an external device through communicating section 32 (input), based on the input signals (command information) sent from operating section 11, to generate the image information of exposing use, which are outputted to exposure processing section 4. Further, image-processing section 70 applies the conversion processing corresponding to its output mode to the processed image data, so as to output the converted image data. Image-processing section 70 outputs the converted image data to CRT 8, image writing section 15, communicating section 33 (output), etc.

Exposure processing section 4 exposes the photosensitive material based on the image signals, and outputs the photosensitive material to print creating section 5. In print creating section 5, the exposed photosensitive material is developed and dried to create prints P1, P2, P3. Incidentally, prints P1 include service size prints, high-vision size prints, panorama size prints, etc., prints P2 include A4-size prints, and prints P3 include visiting card size prints.

Film scanning section 9 reads the frame image data from developed negative film N acquired by developing the negative film having an image captured by an analogue camera. Reflected document input section 10 reads the frame image data from print P (such as photographic prints, paintings and calligraphic works, various kinds of printed materials) made of a photographic printing paper on which the frame image is exposed and developed, by means of the flat bed scanner.

Image reading section 14 reads the frame image information stored in PC card 13a and floppy (Registered Trade Mark) disc 13b to transfer the acquired image information to control section 7. Further, image reading section 14 is provided with PC card adaptor 14a, floppy disc adaptor 14b serving as an image transferring means 30. Still further, image reading section 14 reads the frame image information stored in PC card 13a inserted into PC card adaptor 14a and floppy disc 13b inserted into floppy disc adaptor 14b to transfer the acquired image information to control section 7. For instance, the PC card reader or the PC card slot, etc. can be employed as PC card adaptor 14a.

Communicating section 32 (input) receives image signals representing the captured image and print command signals sent from a separate computer located within the site in which image-recording apparatus 1 is installed and/or from a computer located in a remote site through Internet, etc.

Image writing section 15 is provided with floppy disk adaptor 15a, MO adaptor 15b and optical disk adaptor 15c, serving as image conveying section 31. Further, according to the writing signals inputted from control section 7, image writing section 15 writes the data, generated by the image-processing method embodied in the present invention, into floppy disk 16a inserted into floppy disk adaptor 15a, MO disc 16b inserted into MO adaptor 15b and optical disk 16c inserted into optical disk adaptor 15c.

Data storage section 71 stores the image information and its corresponding order information (including information of a number of prints and a frame to be printed, information of print size, etc.) to sequentially accumulate them in it.

The template memory section 272 memorizes the sample image data (data showing the background image and illustrated image) corresponding to the types of information on sample identification D1, D2 and D3, and memorizes at least one of the data items on the template for setting the composite area with the sample image data. When a predetermined template is selected from among multiple templates previously memorized in the template memory section 272 by the operation of the operator, the selected template is merged with the frame image information. Then, the sample image data, selected on the basis of designated sample identification information D1, D2 and D3, are merged with image data and/or character data ordered by a client, so as to create a print based on the designated sample image. This merging operation by this template is performed by the widely known chromakey technique.

The types of information on sample identification D1, D2 and D3 for specifying the print sample are arranged to be inputted from the operation section 211. Since the types of information on sample identification D1, D2 and D3 are recorded on the sample or order sheet, they can be read by the reading section such as an OCR. Alternatively, they can be inputted by the operator through a keyboard.

As described above, sample image data is recorded in response to sample identification information D1 for specifying the print sample, and the sample identification information D1 for specifying the print sample is inputted. Based on the inputted sample identification information D1, sample image data is selected, and the selected sample image data and image data and/or character data based on the order are merged to create a print according to the specified sample. This procedure allows a user to directly check full-sized samples of various dimensions before placing an order. This permits wide-ranging user requirements to be satisfied.

The first sample identification information D2 for specifying the first sample, and first sample image data are memorized; alternatively, the second sample identification information D3 for specifying the second sample, and second sample image data are memorized. The sample image data selected on the basis of the specified first and second sample identification information D2 and D3, and ordered image data and/or character data are merged with each other, and a print is created according to the specified sample. This procedure allows a greater variety of images to be created, and permits wide-ranging user requirements to be satisfied.

Operating section 11 is provided with information inputting means 12. Information inputting means 12 is constituted by a touch panel, etc., so as to output a push-down signal generated in information inputting means 12 to control section 7 as an inputting signal. Incidentally, it is also applicable that operating section 11 is provided with a keyboard, a mouse, etc. Further, CRT 8 displays image information, etc., according to the display controlling signals inputted from control section 7.

Communicating section 33 (output) transmits the output image signals, representing the captured image and processed by the image-processing method embodied in the present invention, and its corresponding order information to a separate computer located within the site in which image-recording apparatus 1 is installed and/or to a computer located in a remote site through Internet, etc.

As shown in FIG. 5, the image recording apparatus 1 is provided with: an input section for capturing the digital image data of various types and image information obtained by dividing the image document and measuring a property of light; an image processing section; an image outputting section for displaying or printing out the processed image on the image recording medium; and a communications section (output) for sending the image data and accompanying order information to another computer in the facilities through a communications line or a remote computer through Internet, etc.

The following describes the processing to be implemented by the image processing section 70 of FIG. 5, with reference to the first to fourth embodiments:

### Embodiment 1

The configuration of the first embodiment will be described first:

Configuration of Image Processing Section

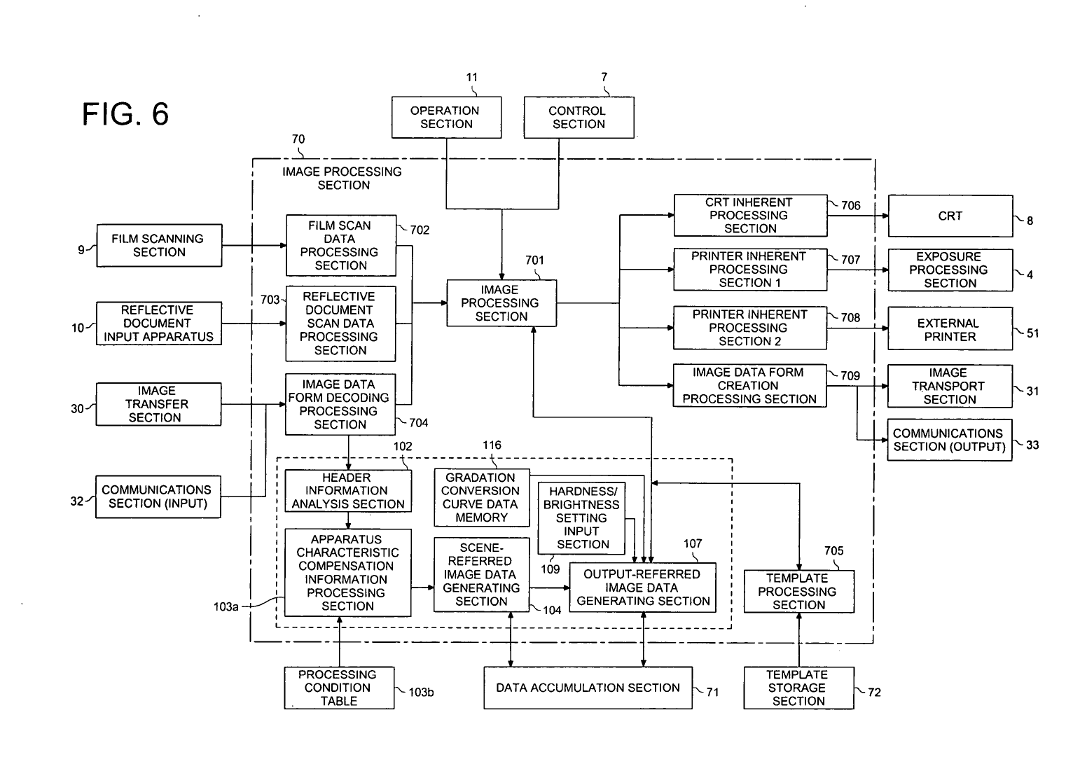

FIG. 6 is block diagram showing the functional configuration of an image processing section 70. The image processing section 70 consists of an image adjustment processing section 701, film scan data processing section 702, reflective document scan data processing section 703, image data form decoding processing section 704, template processing section 705, CRT inherent processing section 706, printer inherent processing section (1) 707, printer inherent processing section (2) 708, image data form creation processing section 709, header information analysis section 102, apparatus characteristic compensation information processing section 103a, scene-referred image data generating section 104, output-referred image data generating section 107, gradation conversion curve data memory 116, and hardness/brightness setting input section 109, as shown in FIG. 6.

The film scan data processing section 702 applies processing of calibration inherent to the film scanner section 9, negative/positive reversal (in the case of a negative original), removal of contamination and damage, gray balance adjustment, contract adjustment, granular noise elimination, sharpness enhancement and others, to the image data inputted from a film scanner section 9. The film scan data processing section 702 then outputs the image data having been processed, to the image adjustment processing section 701. The film size, negative/positive category and information on the major subject recorded optically or magnetically on a film are also outputted to the image adjustment processing section 701.

The reflective document scan data processing section 703 applies processing of calibration inherent to the reflective document input apparatus 10, negative/positive reversal (in the case of a negative original), removal of contamination and damage, gray balance adjustment, contract adjustment, noise elimination, sharpness enhancement and others, to the image data inputted from a reflective document input apparatus 10, and outputs the image data having been processed, to the image adjustment processing section 701.

The image data form decoding processing section 704 applies the processing of decompression of the compressed symbol, conversion of color data representation method and others, as required, to the image data inputted from the image transfer section 30a and/or communications section (input) 32 according to the format of the image data, and converts the image data into the format suited for computation in the image processing section 70. Then the image data form decoding processing section 704 outputs the resulting data, to the image adjustment processing section 701. When the size of the output image has been specified from any one of the operation section 11, communications section (input) 32 and image transfer section 30, the image data form decoding processing section 704 detects the specified information, and outputs it to the image adjustment processing section 701. Information on the size of the output image specified by the image transfer section 30 is embedded in the header information and tag information acquired by the image transfer section 30.

Based on the instruction from the operation section 11 or control section 7, the image adjustment processing section 701 applies the image processing for ensuring a preferable impression for the viewing of an image on an output media, to the image data received from the film scanner section 9, reflective document input apparatus 10, mage transfer section 30, communications section (input) 32 and template processing section 705, in the manner to be described later, and generates the digital image data to be outputted. Then the image adjustment processing section 701 outputs it to the CRT inherent processing section 706, printer inherent processing section (1) 707, printer inherent processing section (2) 708, image data form creation processing section 709 and data accumulation section 71. In this image processing, based on the instruction from the operation section 11 and control section 7, the image adjustment processing section 701 reads a gradation conversion curve for creating the output-referred image data suited for the output device and output media, from the gradation conversion curve data memory 116, and outputs it to the output-referred image data generating section 107.

Based on the instruction from the image adjustment processing section 701, the template processing section 705 reads the specified image data (template) from the template storage 72 to apply template processing whereby the image data to be subjected to image processing is superimposed upon the template. The image data having been subjected to template processing is then outputted to the image adjustment processing section 701.

The header information analysis section 102 decodes the image-capturing device characteristic compensation, when the image data form decoding processing section 704 has verified that the image data has been inputted from the mage transfer section 30 or communications section (input) 32.

By referring to the processing condition table 103b, the apparatus characteristic compensation information processing section 103a determines the image processing conditions based on the image-capturing device characteristic compensation data. According to the image processing conditions, the scene-referred image data generating section 104 generates the scene-referred image data determined by the apparatus characteristic compensation information processing section 103a.

The output-referred image data generating section 107 generates the output-referred image data based on the gradation conversion curve data and scene-referred image data. In conformity to the compensation value of the hardness and brightness specified by the hardness/brightness setting input section 109, the output-referred image data generating section 107 applies processing of correction (change) to the gradation conversion curve; thus, the output-referred image data is again generated.

The CRT inherent processing section 706 applies processing of changing the number of pixels or color matching, to the image data inputted from the image adjustment processing section 701, as required, and outputs the image data for display synthesized with the information requiring display of the control information or the like, to the CRT8.

The printer inherent processing section (1) 707 applies processing of calibration inherent to the printer, color matching and changing the number of pixels, as required, and outputs the processed image data to the exposure processing section 4.

When an external printer 51 such as a large-format inkjet printer can be connected to the image recording apparatus 1 of the present invention, each printer to be connected is provided with a printer inherent processing section (2) 708. This printer inherent processing section (2) 708 applies processing of calibration inherent to the printer, color matching and changing the number of pixels, as required, and outputs the processed image data to the external printer 51.

The image data form creation processing section 709 converts the general-purpose image formant represented by JPEG, TIFF and Exif to the image data inputted from the image adjustment processing section 701, as required, and outputs the processed image data to an image transport section 31 and communications section (output) 33.

The image data created by the output-referred image data generating section 107 is based on the premise that processing be applied by the CRT inherent processing section 706, printer inherent processing section (1) 707, printer inherent processing section (2) 708 and image data form creation processing section 709. In the image data form creation processing section 709, the status file for CRT, exposure output section, external printer, communications section (output) and others has been attached to demonstrate that the image data has been optimized, based on the format of the output-referred image data; and after that, each of the image data item can be outputted to the image transport section 31.

The classification of the film scan data processing section 702, reflective document scan data processing section 703, image data form decoding processing section 704, image adjustment processing section 701, CRT inherent processing section 706, printer inherent processing section (1) 707, printer inherent processing section (2) 708, image data form creation processing section 709, as shown in FIG. 6, is provided to assist understanding of the functions of the image processing section 70. They need not be always realized as independent devices. For example, the classification may be realized in the form of showing the categories of the software processing in a single CPU.

The classification of the header information analysis section 102, apparatus characteristic compensation information processing section 103a, image-capturing information data processing section 106, scene-referred image data generating section 104 and output-referred image data generating section 107 is also provided to assist understanding of the functions of the image processing section 70. They need not be always realized as independent devices. For example, the classification may be realized in the form of showing the categories of the software processing in a single CPU.

Configuration of Image Processing Apparatus

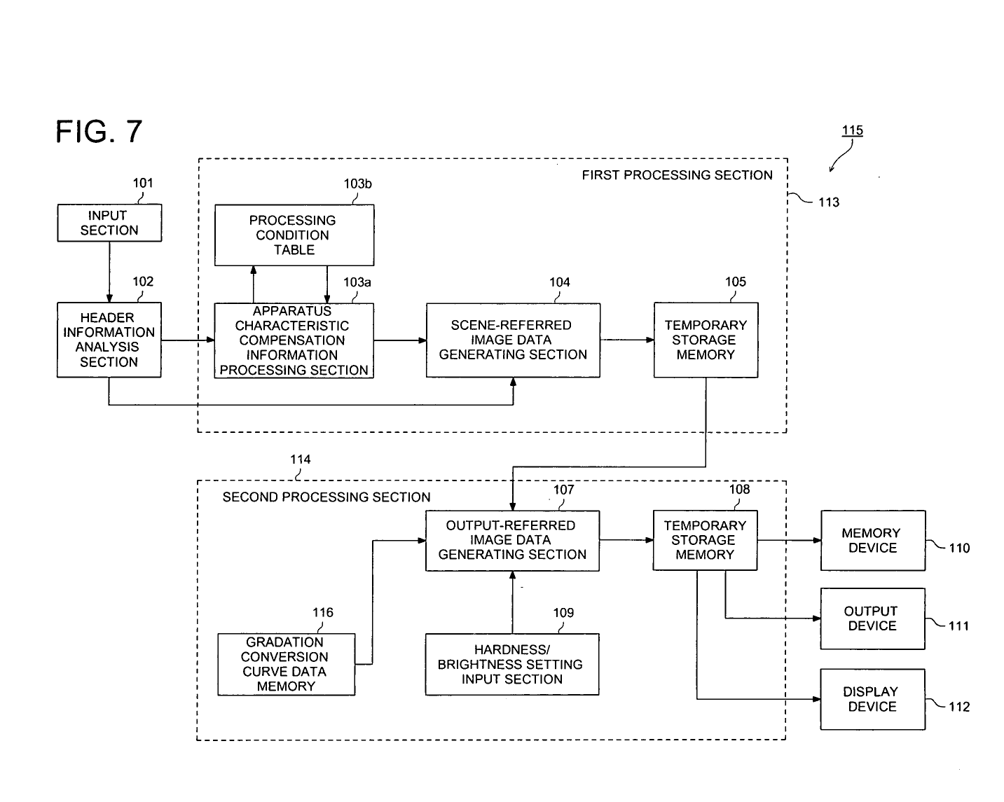

Referring to the block diagram of FIG. 7, the following describes the image processing apparatus 115: The image processing apparatus 115 forms part of the image processing section 70 of FIG. 6, and consists of an input section 101, header information analysis section 102, first processing section 113 and second processing section 114, as shown in FIG. 7. The first processing section 113 is connected with the header information analysis section 102, and the second processing section 114 is connected to the memory device 110, output device 111 and display device 112.

The input section 101 reads the image data recorded by an image-capturing apparatus, from the memory device. The header information analysis section 102 analyzes the header information of the image data read from the input section 101, and separates the image-capturing device characteristic compensation data attached to the image data, from subject information.

The first processing section 113 consists of apparatus characteristic compensation information processing section 103a, scene-referred image data generating section 104 and temporary storage memory 105.

By reference to the processing condition table 103b, the apparatus characteristic compensation information processing section 103a determines the scene-referred image data generating conditions from the image-capturing device characteristic compensation data, and outputs the determined scene-referred image data generating conditions to the scene-referred image data generating section 103.

According to the scene-referred image data generating conditions determined by the apparatus characteristic compensation information processing section 103a, the scene-referred image data generating section 104 generates the scene-referred image data having undergone processing of image-capturing device characteristic compensation, from the image data to be processed. The temporary storage memory 105 temporarily stores the scene-referred image data generated by the scene-referred image data generating section 104.

A setting input section (not illustrated) outputs the operation information on the category of the memory device 110 for outputting the digital image and output device 111 display device 112, to the output-referred image data generating section 107 of the second processing section 114.

The second processing section 114 consists of the gradation conversion curve data memory 116, hardness/brightness setting input section 109, output-referred image data generating section 107 and temporary storage memory 108.

The gradation conversion curve data memory 116 stores the gradation conversion curve data, specific region data and traveling locus data for each output medium.

The hardness/brightness setting input section 109 is provided with an input device for inputting the hardness compensation value (adjusting value) and brightness compensation value (adjusting value) of the output-referred image data.

When the scene-referred image data stored in the temporary storage memory 105 has been read and a output medium has been specified by the setting input section (not illustrated), the output-referred image data generating section 107 reads out the gradation conversion curve data corresponding to the specified output medium from the gradation conversion curve data memory 116, and generates the output-referred image data based on the read gradation conversion curve data. When the hardness compensation value has been inputted from the hardness/brightness setting input section 109, the output-referred image data generating section 107 reads the specific region data from the gradation conversion curve data memory 116, and performs the processing of correcting (changing) the gradation conversion curve, based on the inputted hardness compensation value. Further, when the brightness compensation value has been inputted from the hardness/brightness setting input section 109, the output-referred image data generating section 107 reads the traveling locus data from the gradation conversion curve data memory 116, and performs the processing of correcting (changing) the gradation conversion curve, based on the inputted brightness compensation value. Further, based on the gradation conversion curve corrected by the input of the hardness compensation value and brightness compensation value, the output-referred image data generating section 107 regenerates the output-referred image data. The procedure of creating a new gradation conversion curve by correcting the gradation conversion curve will be described later.

The temporary storage memory 108 temporarily stores the output-referred image data generated by the output-referred image data generating section 107. The data stored in the temporary storage memory 108 is outputted to any one of the memory device 110, output device 111 and display device 112 according to the operation information from the setting input section (not illustrated).

Creation of Gradation Conversion Curve

The method for creating an initial gradation conversion curve will be described first. The gradation conversion curve is created by using the brightness value (luminance) obtained by applying the following formulas (1) through (4) specified in the IEC61966-2-1 and the formula (5) specified in the JIS Z8729 to the scene-referred image data.

$$\begin{matrix}[ Mathematical Formula 1 ] & \\ {R}_{sRGB}^{′} = {R}_{sRGB ( 8 )} / 255 & ( 1 ) \\ {G}_{sRGB}^{′} = {G}_{sRGB ( 8 )} / 255 & \\ {B}_{sRGB}^{′} = {B}_{sRGB ( 8 )} / 255 & \\ [ Mathematical Formula 2 ] & \\ {sRGB}^{′} > 0.03928 & ( 2 ) \\ {R}_{sRGB} = {\{ ( {R}_{sRGB}^{′} + 0.055 ) / 1.055 \}}^{2.4} & \\ {G}_{sRGB} = {\{ ( {G}_{sRGB}^{′} + 0.055 ) / 1.055 \}}^{2.4} & \\ {B}_{sRGB} = {\{ ( {B}_{sRGB}^{′} + 0.055 ) / 1.055 \}}^{2.4} & \\ [ Mathematical Formula 3 ] & \\ {sRGB}^{′} \leq 0.03928 & ( 3 ) \\ {R}_{sRGB} = {R}_{sRGB}^{′} / 12.92 & \\ {G}_{sRGB} = {G}_{sRGB}^{′} / 12.92 & \\ {B}_{sRGB} = {B}_{sRGB}^{′} / 12.92 & \\ [ Mathematical Formula 4 ] & \\ ( \begin{matrix}X \\ Y \\ Z\end{matrix} ) = ( \begin{matrix}0.4124 & 0.3576 & 0.1805 \\ 0.2126 & 0.7152 & 0.0722 \\ 0.0193 & 0.1192 & 0.9505\end{matrix} ) ( \begin{matrix}{R}_{sRGB} \\ {G}_{sRGB} \\ {B}_{sRGB}\end{matrix} ) & ( 4 ) \\ [ Mathematical Formula 5 ] & \\ \begin{matrix}{L}^{*} = 116 \times {( Y / {Y}_{n} )}^{( 1 / 3 )} - 16 & & ( where Y / {Y}_{n} > 0.008856 )\end{matrix} & ( 5 ) \\ \begin{matrix}{L}^{*} = 903.29 \times ( Y / {Y}_{n} ) & & & & ( where Y / {Y}_{n} \leq 0.008856 )\end{matrix} & \\ {Y}_{n} = 1 ( {D}_{65} ) & \end{matrix}$$

Formulas (1) through (4) show conversion from the 8-bit image data (R_{sRGB(8)}, G_{sRGB(8)} and B_{sRGB(8)}) to tristimulus values (X, Y, Z) of a color matching function. The color matching function in the sense in which it is used here refers to the function showing the distribution of spectral sensitivity for human eyes. Here the sRGB in formulas (1) through (4) indicates that the RGB value of the image data conforms to the sRGB standard. Numeral (8) in formula (1) indicates 8-bit (0 through 255) image data.

In formula (5), L* denotes brightness. The gradation conversion curve defines the relationship between the input and output values of brightness alone. This eliminates the use of a*b*, and only L* is worked out. The Yn in formula (5) indicates “Y” of the standard white plate, and D₆₅ shows the tristimulus value when the light having a color temperature of 6500K is applied to the standard white plate. Yn=1 in formula (5).

When L* has been found out by the formula (5), the initial gradation conversion curve is created by setting the initial hardness and brightness values and a predetermined position in the specific range. For example, the hardness of L*=20 through 50 can be set to 1.42, the hardness of L*=20 through 75 to 1.35, and input L* as a position in the specific region (fixed region) to 44.4. The initial hardness and brightness values and a predetermined position in the specific range can be set for each user by the hardness/brightness setting input section 109 or operation section 11, and can be stored in the gradation conversion curve data memory 116.

The following shows the example of the conditional expression for creating a new gradation conversion curve by adjusting the “hardness” and “brightness” using the specific range (fixed range) on the initial gradation conversion curve:

The following two coefficients (F_{c} and F_{L}) are defined as the adjusting coefficients of the gradation conversion curve:
<1> hardness adjusting coefficient F_{c} (initial gradation conversion curve when −2<F_{c}<2, F_{c}=0)<
<2> brightness adjusting coefficient F_{L} (initial gradation conversion curve when −2<F_{L}<2, F_{L}=0)

Formula (6) indicates the variable required to change the gradation conversion curve by these adjusting coefficients:

[Mathematical Formula 6]
L=44.4−1.331×F_{c}−5.788×F_{L}
G_{S}=1.42+0.284×F_{c}+0.088×F_{L}
G=1.35+0.264×F_{c}+0.051×F_{L}
L_{S}=(G_{S}×L−30)/G_{S}
Lₕ=(G_{S}×L_{S}+55)/G (6)
In formula (6), L denotes input L* as output L*=50μL_{S} indicates input L* as output L*=20, and Lₕ shows input L* as output L*=75. Gs indicates hardness when input L*=20 through 50, and G shows hardness when input L*=20 through 75.

Based on Lₛ, L and Lₕ worked out from formula (6), a smooth curved passing through five points of (0, 0), (Lₛ, 20), (L, 50), (Lₕ, 75) and (100, 100) can be calculated by tertiary spline interpolation where the both-end condition of spline interpolation is second order differential value=0. The following describes the spline interpolation:

Given points are assumed as x₀, x₁, x₂, . . . , xₙ, and their functional values are defined as shown in formula 7.

[Mathematical Formula 7]
fᵣ=f(xᵣ) (r=0, 1, 2, . . . , n) (7)

Further, the sub-class obtained by dividing the closed interval [a, b] by these split points is defined as follows: [xⱼ, xⱼ+1] (0≦j≦n−1) a=x₀<x₁<x₂, . . . <xₙ, =b₀.

The second order continuously differentiable tertiary piecewise polynomial in the interval [a, b] is called tertiary spline function, and is expressed as s(x). This tertiary spline function can be expressed for each divided subclass [xⱼ, xⱼ₊1] by the polynomial sⱼ(x) defined by formula (9).

$$\begin{matrix}[ Mathematical Formula 8 ] & \\ \begin{matrix}{h}_{j} = {x}_{{j}_{+ 1}} - {x}_{j} & & ( 0 \leq j \leq n - 1 )\end{matrix} & ( 8 ) \\ ( \frac{{h}_{j}}{6} ) {u}_{j + 1} + ( \frac{{h}_{j - 1} + {h}_{j}}{3} ) {u}_{j} + ( \frac{{h}_{j - 1}}{6} ) {u}_{j - 1} = & \\ ( \frac{1}{{h}_{j}} ) {f}_{j + 1} - ( \frac{1}{{h}_{j}} + \frac{1}{{h}_{j - 1}} ) {f}_{j} + ( \frac{1}{{h}_{j - 1}} ) {f}_{j - 1} & \\ {u}_{0} = {u}_{n} = 0 & \end{matrix}$$

From formula (8), u₀, u₁, u, . . . , nₙ are found, and are substituted into the following formula (9):

$$\begin{matrix}[ Mathematical Formula 9 ] & \\ {S}_{j} ( x ) = - \frac{{u}_{j}}{6 {h}_{j}} {( x - {x}_{j + 1} )}^{3} + \frac{{u}_{j + 1}}{6 {h}_{j}} {( x - {x}_{j} )}^{3} + & ( 9 ) \\ ( \frac{{f}_{j + 1}}{{h}_{j}} - \frac{{u}_{j + 1} {h}_{j}}{6} ) ( x - {x}_{j} ) - ( \frac{{f}_{j}}{{h}_{j}} - \frac{{u}_{j} {h}_{j}}{6} ) ( x - {x}_{j + 1} ) & \end{matrix}$$

Other specific examples of the spline interpolation that can be used are found in:
Ispline function in MathCAD200, Math Soft Inc.;
SPLC function in T. Watanabe and R. Natori under the supervision of T. Oguni, “Software for Numerical Calculation by Fortran 77”, Maruzen, P. 248 (used as DF(1)=DF(2)=0, IOPT(1)=IOPT(2)=1);
Spline Function in Y. Kurose, Y. Matsushima and T. Matsuo, “Calculation Subroutine Library for Science and Technology in C-language”, Keigaku Shuppan, P. 162;
Spline Function in N. Mikami; “Algorithm Textbook”, CQ Shuppan, P. 110 (Spline Function); and
Spline Function in W. H. Press, S. A. Teukolsky, W. T. Vetterling, B. P. Flannery, “Numerical Recipes in C, Japanese Version”; Gijutsu Hyoronsha, P. 106.

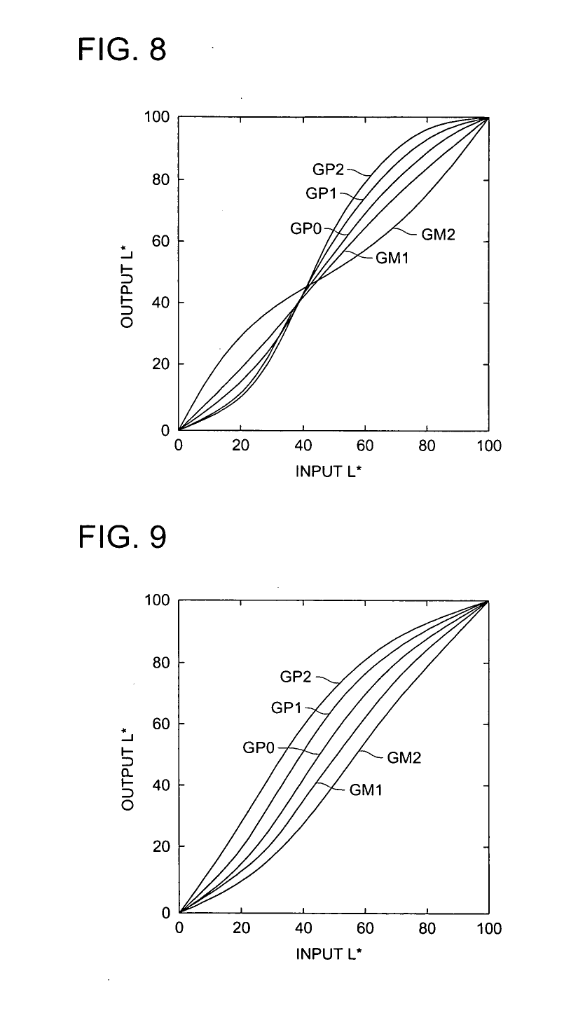

FIG. 8 shows the gradation conversion curve when the hardness adjusting coefficient F_{c} is −2, −1, 0, +1 and +2, and brightness adjusting coefficient F_{L} is 0. In FIG. 8, the curve GP2 shows the gradation conversion curve when F_{c}=+2, the curve GP1 when F_{c}=+1, the curve GP0 when F_{c}=0, the curve GM1 when F_{c}=−1, and the curve GM2 when F_{c}=−2.

FIG. 9 shows the gradation conversion curve when the brightness adjusting coefficient F_{L} is −2, −, 0, +1 and +2, and hardness adjusting coefficient F_{c} is 0. In FIG. 9, the curve GP2 shows the gradation conversion curve when F_{L}=+2, the curve GP1 when F_{L}=+1, the curve GP0 when F_{L}=0, the curve GM1 when F_{L}=−1, and the curve GM2 when F_{L}=−2.

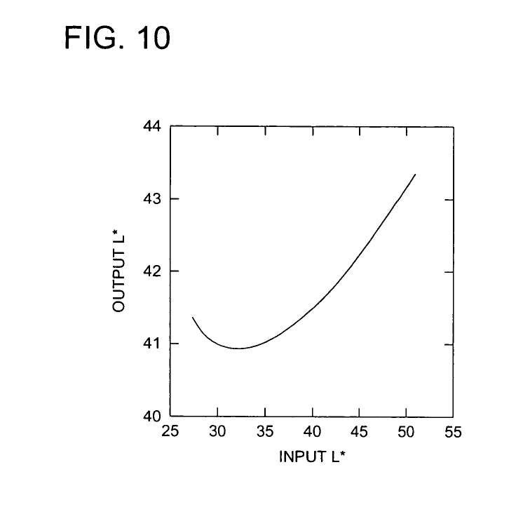

FIG. 10 shows the traveling locus of the specific range (fixed range) when the brightness adjusting coefficient F_{L} is −2, −, 0, +1 and +2, and hardness adjusting coefficient F_{c} is 0. The aforementioned method of creating the gradation conversion curve is applicable to the following embodiments. It should be noted that the method of creating the gradation conversion curve not limited to the aforementioned one.

Operations in the first embodiment will be described:

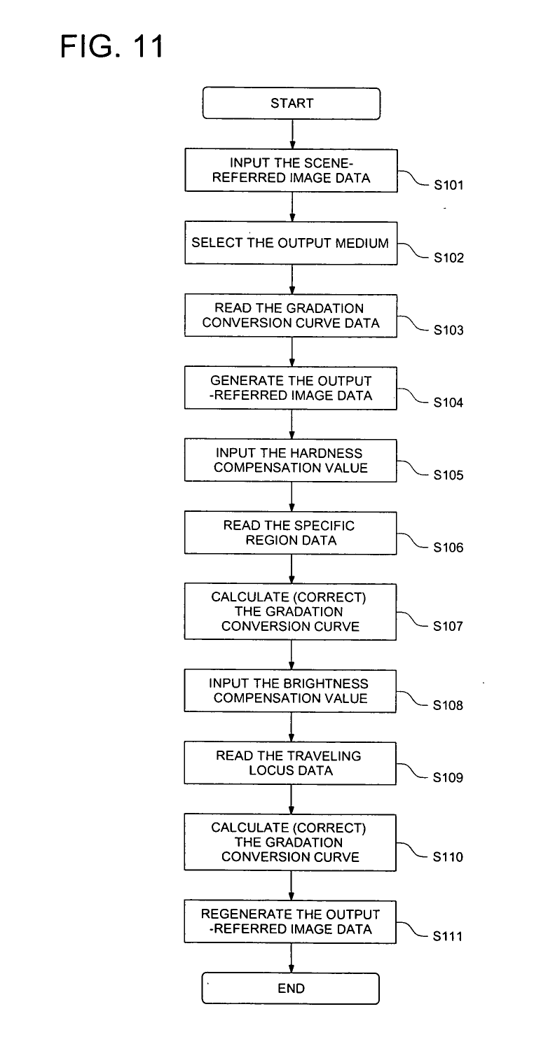

Referring to the flowchart of FIG. 11, the following describes the image processing in the first embodiment:

After scene-referred image data input has been specified (Step S101), the output medium is specified from the setting input section (not illustrated) (Step S102). Then the gradation conversion curve data corresponding to the output medium specified in Step S102 is read from the gradation conversion curve data memory 116 (Step S103). Output-referred image data is created from the scene-referred image data, based on the read gradation conversion curve data (Step S104).

Then, when the hardness compensation value (hardness adjusting value) is inputted by the hardness/brightness setting input section 109 (Step S105), a specific range data is read from the gradation conversion curve data memory 116 (Step S106). According to the inputted hardness compensation value, the gradation conversion curve is corrected (Step S107).

When the brightness compensation value (brightness adjusting value) has been inputted by the hardness/brightness setting input section 109 (Step S108), the traveling locus data is read from the gradation conversion curve data memory 116 (Step S109). According to the inputted brightness compensation value, the gradation conversion curve is corrected (Step S110). Then, based on the corrected gradation conversion curve, output-referred image data is regenerated (Step S111).

As described above, according to the first embodiment, the gradation conversion curve is adjusted based on the hardness compensation value of the output-referred image data, and the gradation conversion curve is adjusted based on the brightness compensation value of the output-referred image data, whereby image processing is performed with minimized interference of respective adjustment effects, and ideal setting of the gradation conversion curve is ensured. Further, this arrangement reduces the load on setting work and improves efficiency in gradation conversion curve setting work.

### Embodiment 2

The configuration of the second embodiment will be described first:

Configuration of Image Processing Section

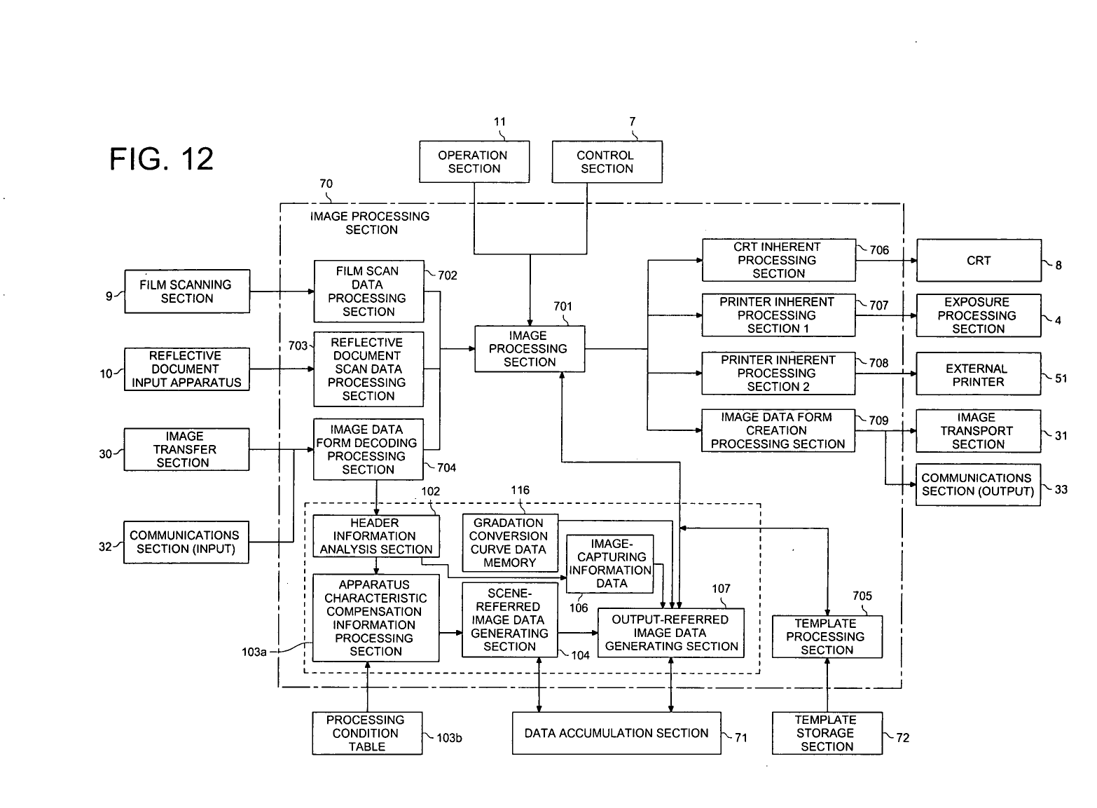

FIG. 12 is block diagram showing the functional configuration of an image processing section 70. As shown in FIG. 12, the image processing section 70 consists of an image adjustment processing section 701, film scan data processing section 702, reflective document scan data processing section 703, image data form decoding processing section 704, template processing section 705, CRT inherent processing section 706, printer inherent processing section (1) 707, printer inherent processing section (2) 708, image data form creation processing section 709, header information analysis section 102, apparatus characteristic compensation information processing section 103a, scene-referred image data generating section 104, output-referred image data generating section 107, gradation conversion curve data memory 116, and image-capturing information data processing section 106. The following describes only the components, constituting the image processing section 70 in the second embodiment, that are different from those of the image processing section 70 in the first embodiment (see FIG. 6):

When the image data form decoding processing section 704 has confirmed that the image data is inputted from the mage transfer section 30 or communications section (input) 32, the header information analysis section 102 decodes the image-capturing device characteristic compensation data and image-capturing information data.

Based on the information on the subject category and image-capturing information included in the image-capturing information data decoded by the header information analysis section 102, the image-capturing information data processing section 106 determines the hardness and brightness compensation values of output-referred image data, and outputs the data on hardness and brightness compensation values to the output-referred image data generating section 107.

The output-referred image data generating section 107 generates the output-referred image data according to the gradation conversion curve data and scene-referred image data. Based on the hardness and brightness compensation values determined by the image-capturing information data processing section 106, the output-referred image data generating section 107 performs processing of correcting (changing) the gradation conversion curve, and regenerates the output-referred image data.

Configuration of Image Processing Section

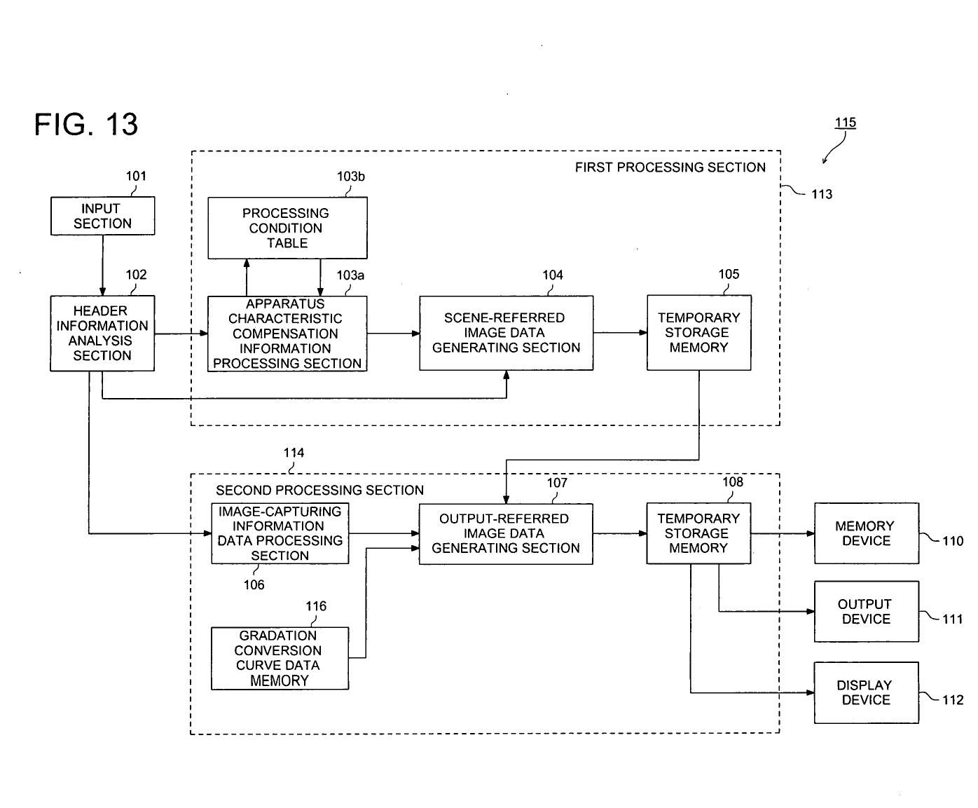

Referring to the block diagram of FIG. 13, the following describes the image processing apparatus 115: The image processing apparatus 115 forms part of the image processing section 70 of FIG. 12, and consists of an input section 101, header information analysis section 102, first processing section 113 and second processing section 114, as shown in FIG. 13. The first processing section 113 is connected with the header information analysis section 102, and the second processing section 114 is connected to the memory device 110, output device 111 and display device 112. The following describes only the components, constituting the image processing section 115 in the second embodiment, that are different from those of the image processing section 115 in the first embodiment (see FIG. 7):

The header information analysis section 102 analyzes the header information of the image data read from the input section 101, and separates it into subject information, image-capturing device characteristic compensation data attached to the image data, and image-capturing information data. The configuration of the first processing section 113 is the same as that in the first embodiment, and will not be described here to avoid duplication.

The second processing section 114 consists of the output-referred image data generating section 107, temporary storage memory 108, gradation conversion curve data memory 116 and image-capturing information data processing section 106. The configuration of the temporary storage memory 108 and gradation conversion curve data memory 116 is the same as that in the first embodiment, and will not be described here to avoid duplication.

Based on the information on the subject category included in the image-capturing information data decoded by the header information analysis section 102, the image-capturing information data processing section 106 determines the hardness compensation values of output-referred image data. Based on the information on image-capturing conditions included in the image-capturing information data, it determines the brightness compensation value (adjusting value) of the output-referred image data. Then the photographic information data 106 and outputs the data on hardness and brightness compensation values to the output-referred image data generating section 107.

The following shows the conditions for adjusting the hardness of the gradation conversion curve in response to the subject category: Table 1 gives the reference values for difference (δ hardness) in hardness (L* 20 through 75) with reference to the initial gradation conversion curve for each subject and value F_{c} (hardness adjusting coefficient).

TABLE 1

| Subject category | δ hardness | F_{C} |
|---|---|---|
| Portrait | −0.05 | −0.19 |
| Outdoors in fine weather | +0.05 | +0.19 |
| Still life | −0.05 | −0.19 |

The following describes an example of the condition for adjusting the brightness (luminance) of the gradation conversion curve in response to the image-capturing conditions. Table 2 gives the reference values for difference (δ brightness) in brightness (L* 50) with reference to the initial gradation conversion curve for each photographic condition and value F_{L} (brightness adjusting coefficient)

TABLE 2

| Photographic conditions | δ brightness | F_{L} |
|---|---|---|
| Flash mode | +5 | +0.9 |
| Backlight | +20 | +3.4 |

When the scene-referred image data stored in the temporary storage memory 105 is read and the output medium is specified by the setting input section (not illustrated), the output-referred image data generating section 107 reads out the gradation conversion curve data corresponding to the specified output medium from the gradation conversion curve data memory 116, and generates the output-referred image data, based on the read gradation conversion curve data. Further, the output-referred image data generating section 107 reads out a specific region from the gradation conversion curve data memory 116, and performs the processing of correcting (changing) the gradation conversion curve, based on the hardness compensation value determined by the image-capturing information data processing section 106. The output-referred image data generating section 107 reads the traveling locus data from the gradation conversion curve data memory 116 and performs the processing of correcting (changing) the gradation conversion curve, based on the brightness compensation value determined by the image-capturing information data processing section 106. The output-referred image data generating section 107 regenerates output-referred image data according to the corrected gradation conversion curve.

Operations in the second embodiment will be described:

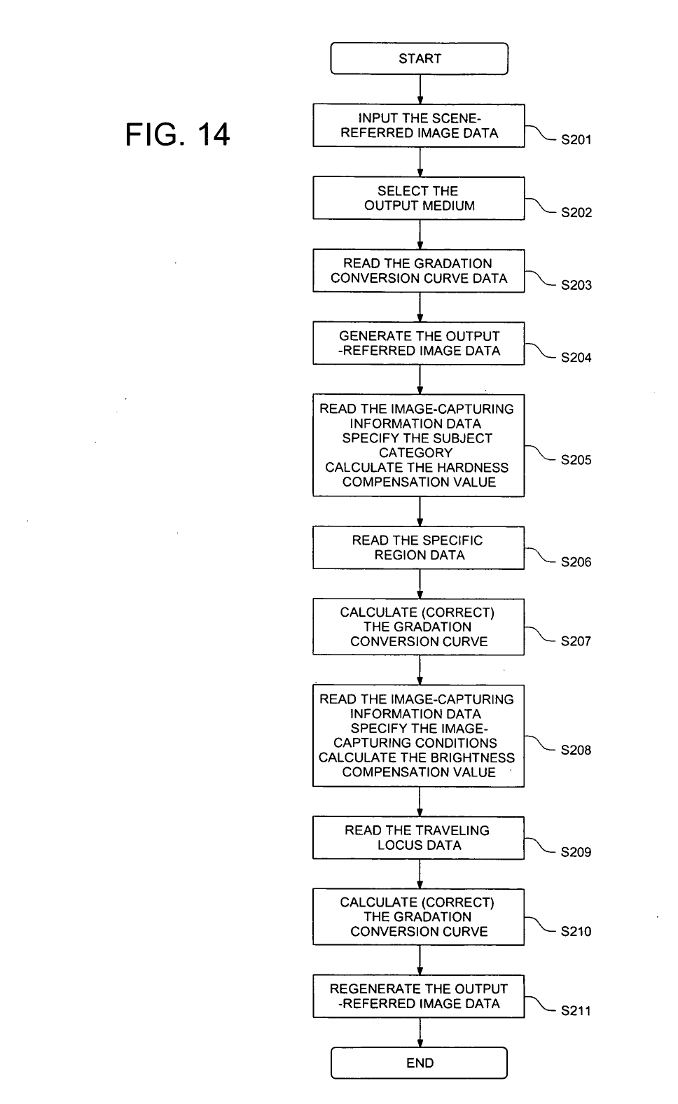

Referring to the flowchart of FIG. 14, the following describes the image processing in the second embodiment:

After scene-referred image data input has been specified (Step S201), the output medium is specified from the setting input section (not illustrated) (Step S202). Then the gradation conversion curve data corresponding to the output medium specified in Step S202 is read from the gradation conversion curve data memory 116 (Step S203). Output-referred image data is created from the scene-referred image data, based on the read gradation conversion curve data (Step S204).

The image-capturing information data stored in the scene-referred image data is read from the header information analysis section 102 and the subject category is specified. Based on Table 1, for example, the hardness compensation value (hardness adjusting value) is determined from the specified subject category (Step S205). When the hardness compensation value has been determined, the specified region data is read from the gradation conversion curve data memory 116 (Step S206). According to the hardness compensation value determined in Step S205, processing is performed to correct the gradation conversion curve (Step S207).

The image-capturing information data recorded in the scene-referred image data header is read from the header information analysis section 102, and the image-capturing conditions are specified. Based on Table 2, for example, the brightness compensation value (brightness adjusting value) is determined from the specified image-capturing conditions (Step S208). When the brightness compensation value has been determined, the traveling locus data is read from the gradation conversion curve data memory 116 (Step S209). According to the brightness compensation value determined in Step S208, processing is performed to correct the gradation conversion curve (Step S210). Then the output-referred image data is regenerated according to the corrected gradation conversion curve (Step S211) and all steps in this image processing terminate.

As described above, according to the second embodiment, the hardness compensation value of the output-referred image data is determined in response to the subject category and the gradation conversion curve is adjusted based on the hardness compensation value. The brightness of the output-referred image data is determined in response to the image-capturing conditions, and the gradation conversion curve is adjusted based on the brightness compensation value. This arrangement ensures ideal setting of the gradation conversion curve, reduces the load on gradation conversion curve setting work and improves efficiency in gradation conversion curve setting work.

### Embodiment 3

The configuration of the third embodiment will be described.

Configuration of Image Processing Section

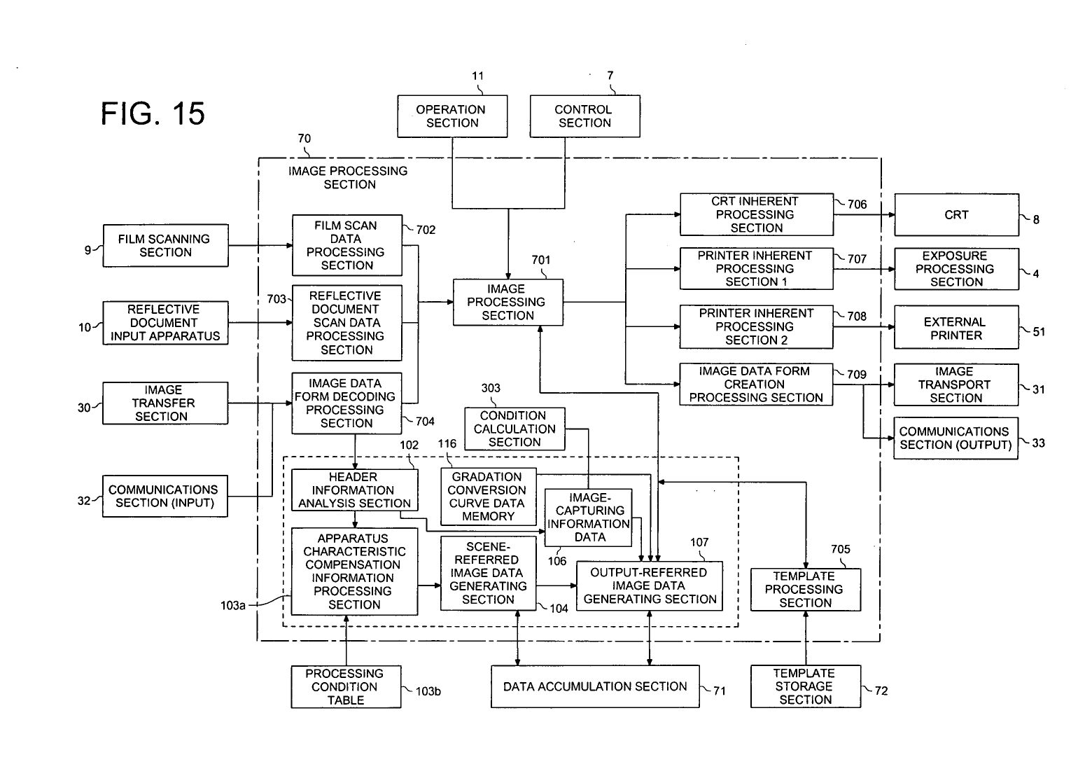

FIG. 15 is a block diagram showing the functional configuration of an image processing section 70. The image processing section 70 consists of an image adjustment processing section 701, film scan data processing section 702, reflective document scan data processing section 703, image data form decoding processing section 704, template processing section 705, CRT inherent processing section 706, printer inherent processing section (1) 707, printer inherent processing section (2) 708, image data form creation processing section 709, header information analysis section 102, apparatus characteristic compensation information processing section 103a, scene-referred image data generating section 104, output-referred image data generating section 107, gradation conversion curve data memory 116, image-capturing information data processing section 106 and condition calculation section 303, as shown in FIG. 15. The following describes only the components, constituting the image processing section 70 in the third embodiment, that are different from those of the image processing section 70 in the second embodiment (see FIG. 12):

Based on the information on the subject category and image-capturing information included in the image-capturing information data decoded by the header information analysis section 102, the image-capturing information data processing section 106 determines whether or not there is a specific combination of the subject category and image-capturing conditions. If there is any, the data on that combination is outputted to the condition calculation section 303.

The condition calculation section 303 stores the applicable hardness and brightness setting data for each combination between the subject category and image-capturing information in advance. According to the data on the combination inputted from the image-capturing information data processing section 106, the hardness and brightness setting values of output-referred image data are determined.

The output-referred image data generating section 107 generates output-referred image data from the gradation conversion curve data and scene-referred image data. Based on the settings of hardness and brightness determined by the condition calculation section 303, the output-referred image data generating section 107 corrects (changes) the gradation conversion curve and regenerates the output-referred image data.

Configuration of Image Processing Apparatus

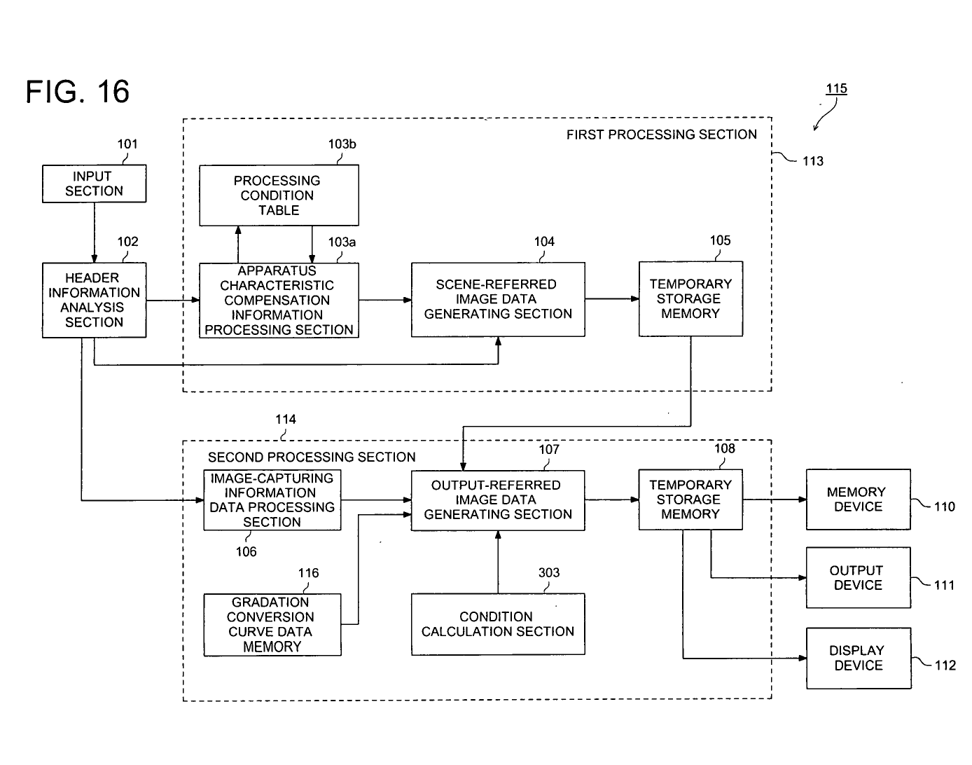

Referring to the block diagram of FIG. 16, the following describes the image processing apparatus 115: The image processing apparatus 115 forms part of the image processing section 70 of FIG. 15, and consists of an input section 101, header information analysis section 102, first processing section 113 and second processing section 114, as shown in FIG. 16. The first processing section 113 is connected with the header information analysis section 102, and the second processing section 114 is connected to the memory device 110, output device 111 and display device 112. The following describes only the components, constituting the image processing section 115 in the third embodiment, that are different from those of the image processing apparatus 115 in the second embodiment (see FIG. 13):

The configuration of the header information analysis section 102 and first processing section 113 is the same as that in the second embodiment, and will not be described here to avoid duplication.

The second processing section 114 consists of the output-referred image data generating section 107, temporary storage memory 108, gradation conversion curve data memory 116, image-capturing information data processing section 106 and condition calculation section 303. The configuration of the temporary storage memory 108 and gradation conversion curve data memory 116 is the same as that in the first embodiment, and will not be described here to avoid duplication.

Based on the information on the subject category and image-capturing information included in the image-capturing information data decoded by the header information analysis section 102, the image-capturing information data processing section 106 determines whether or not there is a specific combination of the subject category and photographic conditions. If there is any, the data on that combination is outputted to the condition calculation section 303.

The condition calculation section 303 stores the applicable hardness and brightness setting data for each combination between the subject category and image-capturing information in advance (see Table 3 to be described later). According to the data on the combination inputted from the photographic information data 106, the hardness and brightness setting values of output-referred image data are determined.

The following describes an example of setting the hardness and brightness compensation values by the combination of the specific subject category and image-capturing conditions. Table 3 gives the reference values for difference (δ hardness) in hardness (L* 20 through 75) with reference to the initial gradation conversion curve and value F_{c} (hardness adjusting coefficient), as well as for difference (δ brightness) in brightness (L* 50) with reference to the initial gradation conversion curve and value F_{L} (brightness adjusting coefficient), when the subject category is a portrait and photographic condition is backlight.

TABLE 3

| Image-capturing conditions | δ hardness | F_{C} |
|---|---|---|
| Flash mode | +0.10 | +0.38 |
| Backlight | +0.20 | +0.76 |
| Image-capturing conditions | δ brightness | F_{L} |
| Flash mode | +5 | +0.9 |
| Backlight | +20 | +3.4 |

When the scene-referred image data stored in the temporary storage memory 105 is read and the output medium is specified by the setting input section (not illustrated), the output-referred image data generating section 107 reads out the gradation conversion curve data corresponding to the specified output medium from the gradation conversion curve data memory 116, and generates the output-referred image data, based on the read gradation conversion curve data. Further, the output-referred image data generating section 107 reads out a specific region from the gradation conversion curve data memory 116, and performs the processing of correcting (changing) the gradation conversion curve, based on the hardness setting determined by the condition calculation section 303. Further, the output-referred image data generating section 107 reads the traveling locus data from the gradation conversion curve data memory 116 and performs the processing of correcting (changing) the gradation conversion curve, based on the brightness compensation value determined by the condition calculation section 303. The output-referred image data generating section 107 regenerates output-referred image data according to the corrected gradation conversion curve.

Operations in the third embodiment will be described:

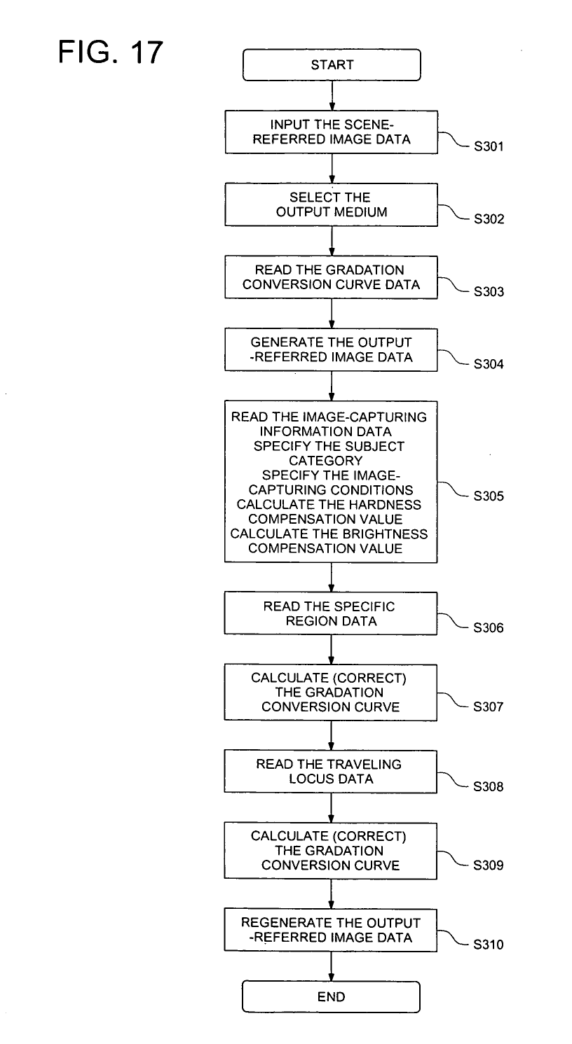

Referring to the flowchart of FIG. 17, the following describes the image processing in the third embodiment:

After scene-referred image data input has been specified (Step S301), the output medium is specified from the setting input section (not illustrated) (Step S302). Then the gradation conversion curve data corresponding to the output medium specified in S302 is read from the gradation conversion curve data memory 116 (Step S303). Output-referred image data is created from the scene-referred image data, based on the read gradation conversion curve data (Step S304).

The image-capturing information data stored in the scene-referred image data is read from the header information analysis section 102, and a combination of the subject category and image-capturing condition are specified. Based on Table 3, for example, the hardness compensation value (hardness adjusting value) and brightness compensation value (brightness adjusting value) are determined from the specified subject category the image-capturing condition (Step S305). When the hardness and brightness compensation values have been determined, the specified region data is read from the gradation conversion curve data memory 116 (Step S306). According to the hardness compensation value determined in Step S305, processing is performed to correct the gradation conversion curve (Step S307).

Then the traveling locus data is read from the gradation conversion curve data memory 116 (Step S308). According to the brightness compensation value determined in Step S305, processing is performed to correct the gradation conversion curve (Step S309). Then the output-referred image data is regenerated according to the corrected gradation conversion curve (Step S310) and all steps in this image processing terminate.

As described above, according to the third embodiment, the hardness and brightness compensation values of the output-referred image data are determined in response to combination of the subject category and image-capturing conditions, and the gradation conversion curve is adjusted based on the hardness and brightness compensation values determined in this way. This arrangement reduces the load on gradation conversion curve setting work and improves efficiency in gradation conversion curve setting work.

### Embodiment 4

The configuration of the fourth embodiment will be described.

Configuration of Image Processing Section

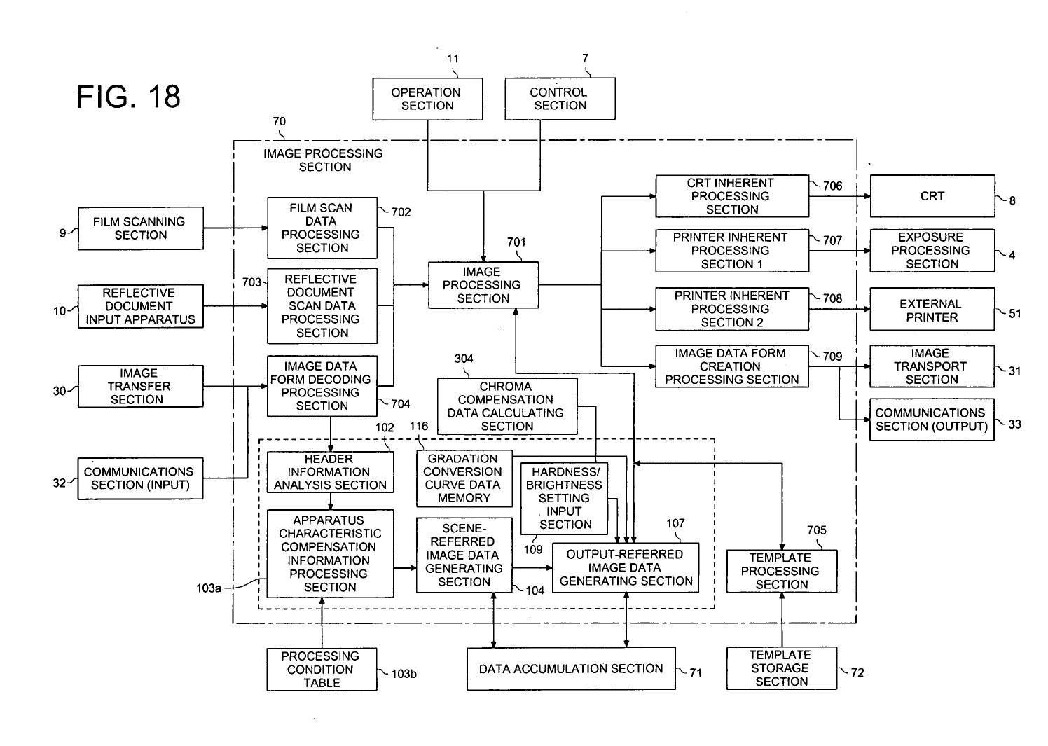

FIG. 18 is a block diagram showing the functional configuration of an image processing section 70. As shown in FIG. 18, the image processing section 70 consists of an image adjustment processing section 701, film scan data processing section 702, reflective document scan data processing section 703, image data form decoding processing section 704, template processing section 705, CRT inherent processing section 706, printer inherent processing section (1) 707, printer inherent processing section (2) 708, image data form creation processing section 709, header information analysis section 102, apparatus characteristic compensation information processing section 103a, scene-referred image data generating section 104, output-referred image data generating section 107, gradation conversion curve data memory 116, hardness/brightness setting input section 109 and chroma compensation data calculating section 304. The following describes only the components, constituting the image processing section 70 in the fourth embodiment, that are different from those of the image processing section 70 in the first embodiment (see FIG. 6):

The chroma compensation data calculating section 304 calculates the amount of chroma adjustment of output-referred image data, based on the hardness compensation value specified by the hardness/brightness setting input section 109.

The output-referred image data generating section 107 generates output-referred image data from the gradation conversion curve data and scene-referred image data. Based on the hardness and brightness compensation values specified by the hardness/brightness setting input section 109, the output-referred image data generating section 107 corrects (changes) the gradation conversion curve. Further, the output-referred image data generating section 107 regenerates the output-referred image data, based on the corrected gradation conversion curve and the amount of chroma adjustment worked out by the chroma compensation data calculating section 304.

Configuration of Image Processing Apparatus

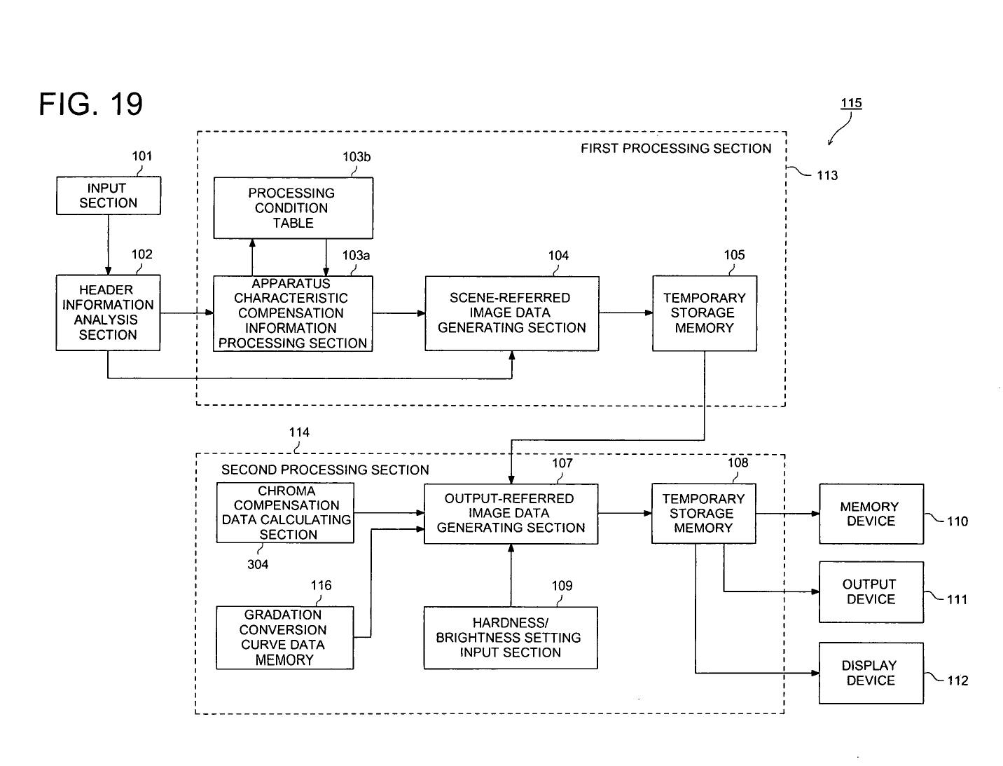

Referring to the block diagram of FIG. 19, the following describes the image processing apparatus 115: The image processing apparatus 115 forms part of the image processing section 70 of FIG. 18, and consists of an input section 101, header information analysis section 102, first processing section 113 and second processing section 114, as shown in FIG. 19. The first processing section 113 is connected with the header information analysis section 102, and the second processing section 114 is connected to the memory device 110, output device 111 and display device 112. The following describes only the components, constituting the image processing section 115 in the fourth embodiment, that are different from those of the image processing section 115 in the first embodiment (see FIG. 7):

The configuration of the header information analysis section 102 and first processing section 113 is the same as that in the first embodiment, and will not be described here to avoid duplication.

The second processing section 114 consists of the output-referred image data generating section 107, temporary storage memory 108, gradation conversion curve data memory 116, hardness/brightness setting input section 109 and chroma compensation data calculating section 304. The configuration of the temporary storage memory 108, gradation conversion curve data memory 116 and hardness/brightness setting input section 109 is the same as that in the first embodiment, and will not be described here to avoid duplication.

The chroma compensation data calculating section 304 works out the amount of chroma adjustment of the output-referred image data in conformity to the hardness compensation value specified by the hardness/brightness setting input section 109. The following shows an example of the formula defining the method for calculating the amount of chroma adjustment in response to the degree of adjusting the gradation conversion curve according to hardness compensation value. Assume that the hardness adjusting coefficient corresponding to the specified hardness adjusting value is F_{c}, the difference (δ hardness) with reference to the initial gradation conversion curve of hardness (L* 25 through 75) is DG, and the amount of chroma adjustment (%) is PS. Then the amount of chroma adjustment PS is expressed as given in the following formula (10).

[Mathematical Formula 10]
D.G=(10−PS)×0.033
F_{c}={(10−PS)×3.8}×0.033 (10)

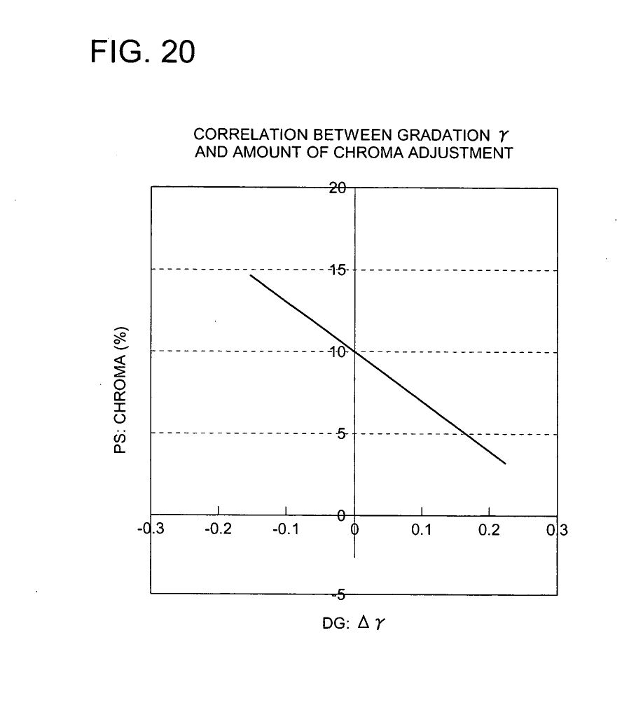

The Formula (10) shows the case wherein the hardness adjusting value is 0, i.e. hardness adjusting efficiency is 0 and the amount of chroma adjustment (amount of enhancement) is set to +10%. FIG. 20 shows the relationship between DG(=δγ) shown in Formula (10).

When the scene-referred image data stored in the temporary storage memory 105 is read and the output medium is specified by the setting input section (not illustrated), the output-referred image data generating section 107 reads out the gradation conversion curve data corresponding to the specified output medium from the gradation conversion curve data memory 116, and generates the output-referred image data, based on the read gradation conversion curve data. Further, the output-referred image data generating section 107 reads the specific range data from the gradation conversion curve data memory 116, when hardness compensation value has been inputted from the hardness/brightness setting input section 109, and performs the processing of correcting (changing) the gradation conversion curve, based on the inputted hardness compensation value. Further, when the brightness compensation value has been inputted from the hardness/brightness setting input section 109, the output-referred image data generating section 107 reads the traveling locus data from the gradation conversion curve data memory 116 and performs the processing of correcting (changing) the gradation conversion curve, based on the inputted brightness compensation value. The output-referred image data generating section 107 regenerates output-referred image data according to the corrected gradation conversion curve and the amount of chroma adjustment worked out by the chroma compensation data calculating section 304.

The following describes the operation of the fourth embodiment.

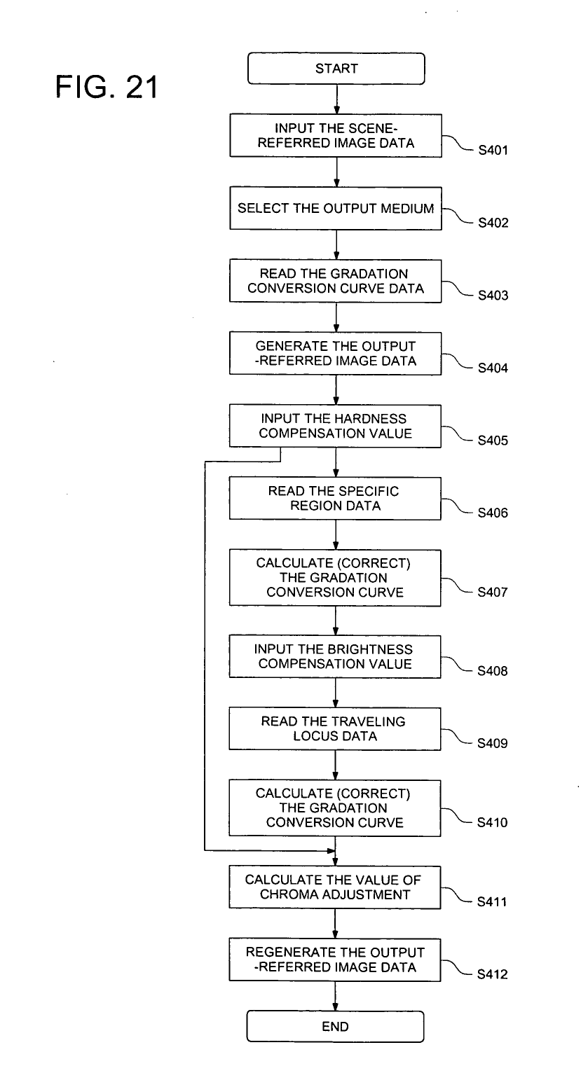

Referring to the flowchart of FIG. 21, image processing in the fourth embodiment will be described.

After scene-referred image data input has been specified (Step S401), the output medium is specified from the setting input section (not illustrated) (Step S402). Then the gradation conversion curve data corresponding to the output medium specified in S402 is read from the gradation conversion curve data memory 116 (Step S403). Output-referred image data is created from the scene-referred image data, based on the read gradation conversion curve data (Step S404).

When the hardness compensation value (hardness adjusting value) has been inputted from the hardness/brightness setting input section 109 (Step S405), specific region data is read from the gradation conversion curve data memory 116 (Step S406), and processing is performed to correct the gradation conversion curve (Step S407) according to the inputted hardness compensation value.

When the brightness compensation value (brightness adjusting value) has been inputted from the brightness/brightness setting input section 109 (Step S408), traveling locus data is read from the gradation conversion curve data memory 116 (Step S409), and processing is performed to correct the gradation conversion curve (Step S410) according to the inputted brightness compensation value.

The amount of chroma adjustment is worked out based on the hardness compensation value inputted in Step S405 (Step S411). Then the output-referred image data is regenerated according to the corrected gradation conversion curve and the amount of chroma adjustment (Step S412), and all steps in this image processing terminate.

As described above, according to the fourth embodiment, the gradation conversion curve is adjusted according to the hardness compensation value of the output-referred image data, and then the gradation conversion curve is adjusted according to the brightness compensation value. The amount of chroma adjustment is determined based on the hardness compensation value, and the output-referred image data is generated based on the corrected gradation conversion curve and amount of chroma adjustment. This arrangement reduces the load on gradation conversion curve setting work and further improves efficiency in the ideal gradation conversion curve setting work.

The aforementioned description in the embodiments can be modified as required, without departing from the spirit of the invention.

For example, it is possible to arrange such a configuration that the hardness of the output-referred image data can be set in response to the subject category and the brightness of the output-referred image data is set in response to image-capturing conditions by a combination between the second and third embodiments. It is also possible to make such arrangements that the hardness and brightness of the output-referred image data is set by a combination of the subject category and image-capturing conditions.

It is further possible to arrange such a configuration through a combination of the second and fourth embodiments that the output-referred image data is set in response to subject category; the brightness of the output-referred image data is set in response to the image-capturing conditions; and the chroma of output-referred image data may be adjusted according to the extent to which the hardness of the output-referred image data is adjusted.

It is still further possible to arrange such a configuration through a combination of the third and fourth embodiments that the hardness and brightness of the output-referred image data is set according to a combination of the subject category and image-capturing information data processing section conditions, and the chroma of output-referred image data may adjusted according to the extent to which the hardness of the output-referred image data is adjusted.

It is still further possible to arrange such a configuration through a combination of the second, third and fourth embodiments that the hardness of the output-referred image data is set according to the subject category, the brightness of the output-referred image data is set in response to the image-capturing conditions; the hardness and brightness of the output-referred image data are set according to a combination of the subject category and image-capturing conditions; and the chroma of output-referred image data may be adjusted according to the extent to which the hardness of the output-referred image data is adjusted.

As described in the foregoing, according to the present invention, the following effects can be attained.

(1) A specific region including a predetermined position on a gradation conversion curve representing the conversion from the scene-referred image data to the output-referred image is assumed as an fixed region, and the shape of the gradation conversion curve is changed, thereby adjusting the hardness of the output-referred image, and changing the shape of the gradation conversion curve in such a way that the specific region will move along the pre-defined curve. Through these steps, the brightness of the output-referred image data is adjusted, whereby the efficiency in the setting of the gradation conversion curve can be improved. This allows the adjustment of the brightness of the output-referred image whose fluctuation in hardness is reduced.

(2) The efficiency in the setting of the gradation conversion curve can be improved by adjusting the hardness of the output-referred image data in response to the category of a subject and adjusting the brightness of the output-referred image data in response to photographic conditions. Further improvement of the efficiency in the setting of the gradation conversion curve can be achieved by adjusting the hardness and brightness of the output-referred image data in response to the combination of the category of a specific subject and photographic conditions.

(3) In response to the adjustment value of the hardness of the output-referred image data, the chroma of the output-referred image data can be adjusted. This arrangement not only improves the efficiency in the setting of the gradation conversion curve but also provides preferable output-referred image data.

Disclosed embodiment can be varied by a skilled person without departing from the spirit and scope of the invention.

1. An image-processing method for generating output-referred image data by applying an optimization processing, for optimizing an output image to be formed on an outputting medium, to scene-referred image data, said image-processing method comprising the steps of:
designating a hardness adjusting value for said output-referred image data;
changing a gradation conversion curve, which is defined for every outputting medium in advance and represents a conversion table for converting said scene-referred image data to said output-referred image data, based on said hardness adjusting value, so as to generate a first-revised gradation conversion curve;
designating a brightness adjusting value for said output-referred image data;
changing said first-revised gradation conversion curve, based on said brightness adjusting value, so as to generate a second-revised gradation conversion curve; and
generating said output-referred image data, based on said second-revised gradation conversion curve;
wherein said first-revised gradation conversion curve is generated by modifying a shape of said gradation conversion curve residing in a region other than a specific region, which serves as a fixed region including a predetermined position on said gradation conversion curve, based on said hardness adjusting value of said output-referred image data; and
wherein said second-revised gradation conversion curve is generated by modifying a shape of said first-revised gradation conversion curve in such a manner that said specific region moves on a predetermined curve defined in advance, based on said brightness adjusting value.

2. An image-processing method for generating output-referred image data by applying an optimization processing, for optimizing an output image to be formed on an outputting medium, to scene-referred image data, said image-processing method comprising the steps of:
determining a hardness adjusting value for said output-referred image data, corresponding to a kind of a subject to be included in said output image;
changing a gradation conversion curve, which is defined for every outputting medium in advance and represents a conversion table for converting said scene-referred image data to said output-referred image data, based on said hardness adjusting value, so as to generate a first-revised gradation conversion curve;
determining a brightness adjusting value for said output-referred image data, corresponding to an image-capturing condition;
changing said first-revised gradation conversion curve, based on said brightness adjusting value, so as to generate a second-revised gradation conversion curve; and
generating said output-referred image data, based on said second-revised gradation conversion curve;
wherein said first-revised gradation conversion curve is generated by modifying a shape of said gradation conversion curve residing in a region other than a specific region, which serves as a fixed region including a predetermined position on said gradation conversion curve, based on said hardness adjusting value of said output-referred image data; and
wherein said second-revised gradation conversion curve is generated by modifying a shape of said first-revised gradation conversion curve in such a manner that said specific region moves on a predetermined curve defined in advance, based on said brightness adjusting value.

3. An image-processing method for generating output-referred image data by applying an optimization processing, for optimizing an output image to be formed on an outputting medium, to scene-referred image data, said image-processing method comprising the steps of:
determining a hardness adjusting value and a brightness adjusting value for said output-referred image data, corresponding to a specific combination of a kind of a subject to be included in said output image and an image-capturing condition;
changing a gradation conversion curve, which is defined for every outputting medium in advance and represents a conversion table for converting said scene-referred image data to said output-referred image data, based on said hardness adjusting value, so as to generate a first-revised gradation conversion curve;
changing said first-revised gradation conversion curve, based on said brightness adjusting value, so as to generate a second-revised gradation conversion curve; and
generating said output-referred image data, based on said second-revised gradation conversion curve;
wherein said first-revised gradation conversion curve is generated by modifying a shape of said gradation conversion curve residing in a region other than a specific region, which serves as a fixed region including a predetermined position on said gradation conversion curve, based on said hardness adjusting value of said output-referred image data; and
wherein said second-revised gradation conversion curve is generated by modifying a shape of said first-revised gradation conversion curve in such a manner that said specific region moves on a predetermined curve defined in advance, based on said brightness adjusting value.

4. An image-processing method for generating output-referred image data by applying an optimization processing, for optimizing an output image to be formed on an outputting medium, to scene-referred image data, said image-processing method comprising the steps of:
designating a hardness adjusting value for said output-referred image data;
changing a gradation conversion curve, which is defined for every outputting medium in advance and represents a conversion table for converting said scene-referred image data to said output-referred image data, based on said hardness adjusting value, so as to generate a first-revised gradation conversion curve;
designating a brightness adjusting value for said output-referred image data;
changing said first-revised gradation conversion curve, based on said brightness adjusting value, so as to generate a second-revised gradation conversion curve; and
determining a chroma adjusting value for said output-referred image data, based on said hardness adjusting value designated in said designating step;
generating said output-referred image data, based on said second-revised gradation conversion curve and said chroma adjusting value determined in said determining step;
wherein said first-revised gradation conversion curve is generated by modifying a shape of said gradation conversion curve residing in a region other than a specific region, which serves as a fixed region including a predetermined position on said gradation conversion curve, based on said hardness adjusting value of said output-referred image data; and
wherein said second-revised gradation conversion curve is generated by modifying a shape of said first-revised gradation conversion curve in such a manner that said specific region moves on a predetermined curve defined in advance, based on said brightness adjusting value.

5. The image-processing method of claim 2, further comprising the step of:
determining a hardness adjusting value and a brightness adjusting value for said output-referred image data, corresponding to a specific combination of a kind of a subject to be included in said output image and an image-capturing condition;
wherein said gradation conversion curve is changed to said first-revised gradation conversion curve, based on said hardness adjusting value determined in said determining step; and
wherein said first-revised gradation conversion curve is changed to said second-revised gradation conversion curve, based on said brightness adjusting value determined in said determining step.

6. The image-processing method of claim 2, further comprising the step of:
determining a chroma adjusting value for said output-referred image data, based on said hardness adjusting value determined in said determining step;
wherein said output-referred image data are generated, based on said second-revised gradation conversion curve and said chroma adjusting value determined in said determining step.

7. The image-processing method of claim 3, further comprising the step of:
determining a chroma adjusting value for said output-referred image data, based on said hardness adjusting value determined in said determining step;
wherein said output-referred image data are generated, based on said second-revised gradation conversion curve and said chroma adjusting value determined in said determining step.

8. The image-processing method of claim 5, further comprising the step of:
determining a chroma adjusting value for said output-referred image data, based on said hardness adjusting value designated in said designating step;
wherein said output-referred image data are generated, based on said second-revised gradation conversion curve and said chroma adjusting value determined in said determining step.

9. The image-processing method of claim 3, wherein said kind of subject is a portrait and said image-capturing condition is a backlight.

10. The image-processing method of claim 4,
wherein, when said hardness adjusting value is set at zero, said brightness adjusting value is set at such a value that chroma components of said output-referred image data are emphasized.

11. The image-processing method of claim 2,
wherein said kind of subject includes at least anyone of a portrait, a landscape and a still life.

12. The image-processing method of claim 2,
wherein said image-capturing condition includes at least anyone of a backlight and a strobe lighting.

13. The image-processing method of claim 1,
wherein, when an input-output value of said gradation conversion curve is L*, said predetermined position included in said specific region is located at such a position that input value L* is smaller than 50 and equal to or greater than 40.

14. The image-processing method of claim 1,
wherein initial values of hardness and brightness on said gradation conversion curve, which is defined for every outputting medium in advance, are stored in a storage, while correlating them with every one of users.

15. An image-processing apparatus for generating output-referred image data by applying an optimization processing, for optimizing an output image to be formed on an outputting medium, to scene-referred image data, said image-processing apparatus comprising:
a first-designating section to designate a hardness adjusting value for said output-referred image data;
a first-changing section to change a gradation conversion curve, which is defined for every outputting medium in advance and represents a conversion table for converting said scene-referred image data to said output-referred image data, based on said hardness adjusting value, so as to generate a first-revised gradation conversion curve;
a second-designating section to designate a brightness adjusting value for said output-referred image data;
a second-changing section to change said first-revised gradation conversion curve, based on said brightness adjusting value, so as to generate a second-revised gradation conversion curve; and
a generating section to generate said output-referred image data, based on said second-revised gradation conversion curve;
wherein said first-changing section generates said first-revised gradation conversion curve by modifying a shape of said gradation conversion curve residing in a region other than a specific region, which serves as a fixed region including a predetermined position on said gradation conversion curve, based on said hardness adjusting value of said output-referred image data; and
wherein said first-changing section generates said second-revised gradation conversion curve by modifying a shape of said first-revised gradation conversion curve in such a manner that said specific region moves on a predetermined curve defined in advance, based on said brightness adjusting value.

16. An image-processing apparatus for generating output-referred image data by applying an optimization processing, for optimizing an output image to be formed on an outputting medium, to scene-referred image data, said image-processing apparatus comprising:
a hardness-determining section to determine a hardness adjusting value for said output-referred image data, corresponding to a kind of a subject to be included in said output image;
a first-changing section to change a gradation conversion curve, which is defined for every outputting medium in advance and represents a conversion table for converting said scene-referred image data to said output-referred image data, based on said hardness adjusting value, so as to generate a first-revised gradation conversion curve;
a brightness-determining section to determine a brightness adjusting value for said output-referred image data, corresponding to an image-capturing condition;
a second-changing section to change said first-revised gradation conversion curve, based on said brightness adjusting value, so as to generate a second-revised gradation conversion curve; and
a generating section to generate said output-referred image data, based on said second-revised gradation conversion curve;
wherein said first-changing section generates said first-revised gradation conversion curve by modifying a shape of said gradation conversion curve residing in a region other than a specific region, which serves as a fixed region including a predetermined position on said gradation conversion curve, based on said hardness adjusting value of said output-referred image data; and
wherein said first-changing section generates said second-revised gradation conversion curve by modifying a shape of said first-revised gradation conversion curve in such a manner that said specific region moves on a predetermined curve defined in advance, based on said brightness adjusting value.

17. An image-processing apparatus for generating output-referred image data by applying an optimization processing, for optimizing an output image to be formed on an outputting medium, to scene-referred image data, said image-processing apparatus comprising:
a determining section to determine a hardness adjusting value and a brightness adjusting value for said output-referred image data, corresponding to a specific combination of a kind of a subject to be included in said output image and an image-capturing condition;
a first-changing section to change a gradation conversion curve, which is defined for every outputting medium in advance and represents a conversion table for converting said scene-referred image data to said output-referred image data, based on said hardness adjusting value, so as to generate a first-revised gradation conversion curve;
a second-changing section to change said first-revised gradation conversion curve, based on said brightness adjusting value, so as to generate a second-revised gradation conversion curve; and
a generating section to generate said output-referred image data, based on said second-revised gradation conversion curve;
wherein said first-changing section generates said first-revised gradation conversion curve by modifying a shape of said gradation conversion curve residing in a region other than a specific region, which serves as a fixed region including a predetermined position on said gradation conversion curve, based on said hardness adjusting value of said output-referred image data; and
wherein said first-changing section generates said second-revised gradation conversion curve by modifying a shape of said first-revised gradation conversion curve in such a manner that said specific region moves on a predetermined curve defined in advance, based on said brightness adjusting value.

18. An image-processing apparatus for generating output-referred image data by applying an optimization processing, for optimizing an output image to be formed on an outputting medium, to scene-referred image data, said image-processing apparatus comprising:
a hardness-designating section to designate a hardness adjusting value for said output-referred image data;
a first-changing section to change a gradation conversion curve, which is defined for every outputting medium in advance and represents a conversion table for converting said scene-referred image data to said output-referred image data, based on said hardness adjusting value, so as to generate a first-revised gradation conversion curve;
a brightness-designating section to designate a brightness adjusting value for said output-referred image data;
a second-changing section to change said first-revised gradation conversion curve, based on said brightness adjusting value, so as to generate a second-revised gradation conversion curve; and
a chroma-determining section to determine a chroma adjusting value for said output-referred image data, based on said hardness adjusting value designated by said hardness-designating section;
a generating section to generate said output-referred image data, based on said second-revised gradation conversion curve and said chroma adjusting value determined by said chroma-determining section;
wherein said first-changing section generates said first-revised gradation conversion curve by modifying a shape of said gradation conversion curve residing in a region other than a specific region, which serves as a fixed region including a predetermined position on said gradation conversion curve, based on said hardness adjusting value of said output-referred image data; and
wherein said first-changing section generates said second-revised gradation conversion curve by modifying a shape of said first-revised gradation conversion curve in such a manner that said specific region moves on a predetermined curve defined in advance, based on said brightness adjusting value.

19. The image-processing apparatus of claim 16, further comprising:
a determining section to determine a hardness adjusting value and a brightness adjusting value for said output-referred image data, corresponding to a specific combination of a kind of a subject to be included in said output image and an image-capturing condition;
wherein said first-changing section changes said gradation conversion curve to said first-revised gradation conversion curve, based on said hardness adjusting value determined by said determining section; and
wherein said second-changing section changes said first-revised gradation conversion curve to said second-revised gradation conversion curve, based on said brightness adjusting value determined by said determining section.

20. The image-processing apparatus of claim 16, further comprising:
a chroma-determining section to determine a chroma adjusting value for said output-referred image data, based on said hardness adjusting value determined by said hardness-determining section;
wherein said generating section generates said output-referred image data, based on said second-revised gradation conversion curve and said chroma adjusting value determined by said chroma-determining section.

21. The image-processing apparatus of claim 17, further comprising:
a chroma-determining section to determine a chroma adjusting value for said output-referred image data, based on said hardness adjusting value determined by said hardness-determining section;
wherein said generating section generates said output-referred image data, based on said second-revised gradation conversion curve and said chroma adjusting value determined by said chroma-determining section.

22. The image-processing apparatus of claim 19, further comprising:
a chroma-determining section to determine a chroma adjusting value for said output-referred image data, based on said hardness adjusting value determined by said hardness-determining section and said determining section;
wherein said generating section generates said output-referred image data, based on said second-revised gradation conversion curve and said chroma adjusting value determined by said chroma-determining section.

23. The image-processing apparatus of claim 17,
wherein said kind of subject is a portrait and said image-capturing condition is a backlight.

24. The image-processing apparatus of claim 18,
wherein, when said hardness adjusting value is set at zero, said brightness adjusting value is set at such a value that chroma components of said output-referred image data are emphasized.

25. The image-processing apparatus of claim 16,
wherein said kind of subject includes at least anyone of a portrait, a landscape and a still life.

26. The image-processing apparatus of claim 16,
wherein said image-capturing condition includes at least anyone of a backlight and a strobe lighting.

27. The image-processing method of claim 15,
wherein, when an input-output value of said gradation conversion curve is L*, said predetermined position included in said specific region is located at such a position that input value L* is smaller than 50 and equal to or greater than 40.

28. The image-processing apparatus of claim 15, further comprising:
a storage section to store initial values of hardness and brightness on said gradation conversion curve, which is defined for every outputting medium in advance, while correlating them with every one of users.

29. An image-recording apparatus for generating output-referred image data by applying an optimization processing, for optimizing an output image to be formed on an outputting medium, to scene-referred image data, and then, recording said output image based on said output-referred image data onto said outputting medium, said image-recording apparatus comprising:
a first-designating section to designate a hardness adjusting value for said output-referred image data;
a first-changing section to change a gradation conversion curve, which is defined for every outputting medium in advance and represents a conversion table for converting said scene-referred image data to said output-referred image data, based on said hardness adjusting value, so as to generate a first-revised gradation conversion curve;
a second-designating section to designate a brightness adjusting value for said output-referred image data;
a second-changing section to change said first-revised gradation conversion curve, based on said brightness adjusting value, so as to generate a second-revised gradation conversion curve; and
a generating section to generate said output-referred image data, based on said second-revised gradation conversion curve;
wherein said first-changing section generates said first-revised gradation conversion curve by modifying a shape of said gradation conversion curve residing in a region other than a specific region, which serves as a fixed region including a predetermined position on said gradation conversion curve, based on said hardness adjusting value of said output-referred image data; and
wherein said first-changing section generates said second-revised gradation conversion curve by modifying a shape of said first-revised gradation conversion curve in such a manner that said specific region moves on a predetermined curve defined in advance, based on said brightness adjusting value.

30. An image-recording apparatus for generating output-referred image data by applying an optimization processing, for optimizing an output image to be formed on an outputting medium, to scene-referred image data, and then, recording said output image based on said output-referred image data onto said outputting medium, said image-recording apparatus comprising:
a hardness-determining section to determine a hardness adjusting value for said output-referred image data, corresponding to a kind of a subject to be included in said output image;
a first-changing section to change a gradation conversion curve, which is defined for every outputting medium in advance and represents a conversion table for converting said scene-referred image data to said output-referred image data, based on said hardness adjusting value, so as to generate a first-revised gradation conversion curve;
a brightness-determining section to determine a brightness adjusting value for said output-referred image data, corresponding to an image-capturing condition;
a second-changing section to change said first-revised gradation conversion curve, based on said brightness adjusting value, so as to generate a second-revised gradation conversion curve; and
a generating section to generate said output-referred image data, based on said second-revised gradation conversion curve;
wherein said first-changing section generates said first-revised gradation conversion curve by modifying a shape of said gradation conversion curve residing in a region other than a specific region, which serves as a fixed region including a predetermined position on said gradation conversion curve, based on said hardness adjusting value of said output-referred image data; and
wherein said first-changing section generates said second-revised gradation conversion curve by modifying a shape of said first-revised gradation conversion curve in such a manner that said specific region moves on a predetermined curve defined in advance, based on said brightness adjusting value.

31. An image-recording apparatus for generating output-referred image data by applying an optimization processing, for optimizing an output image to be formed on an outputting medium, to scene-referred image data, and then, recording said output image based on said output-referred image data onto said outputting medium, said image-recording apparatus comprising:
a determining section to determine a hardness adjusting value and a brightness adjusting value for said output-referred image data, corresponding to a specific combination of a kind of a subject to be included in said output image and an image-capturing condition;
a first-changing section to change a gradation conversion curve, which is defined for every outputting medium in advance and represents a conversion table for converting said scene-referred image data to said output-referred image data, based on said hardness adjusting value, so as to generate a first-revised gradation conversion curve;
a second-changing section to change said first-revised gradation conversion curve, based on said brightness adjusting value, so as to generate a second-revised gradation conversion curve; and
a generating section to generate said output-referred image data, based on said second-revised gradation conversion curve;
wherein said first-changing section generates said first-revised gradation conversion curve by modifying a shape of said gradation conversion curve residing in a region other than a specific region, which serves as a fixed region including a predetermined position on said gradation conversion curve, based on said hardness adjusting value of said output-referred image data; and
wherein said first-changing section generates said second-revised gradation conversion curve by modifying a shape of said first-revised gradation conversion curve in such a manner that said specific region moves on a predetermined curve defined in advance, based on said brightness adjusting value.

32. An image-recording apparatus for generating output-referred image data by applying an optimization processing, for optimizing an output image to be formed on an outputting medium, to scene-referred image data, and then, recording said output image based on said output-referred image data onto said outputting medium, said image-recording apparatus comprising:
a hardness-designating section to designate a hardness adjusting value for said output-referred image data;
a first-changing section to change a gradation conversion curve, which is defined for every outputting medium in advance and represents a conversion table for converting said scene-referred image data to said output-referred image data, based on said hardness adjusting value, so as to generate a first-revised gradation conversion curve;
a brightness-designating section to designate a brightness adjusting value for said output-referred image data;
a second-changing section to change said first-revised gradation conversion curve, based on said brightness adjusting value, so as to generate a second-revised gradation conversion curve; and
a chroma-determining section to determine a chroma adjusting value for said output-referred image data, based on said hardness adjusting value designated by said hardness-designating section;
a generating section to generate said output-referred image data, based on said second-revised gradation conversion curve and said chroma adjusting value determined by said chroma-determining section;
wherein said first-changing section generates said first-revised gradation conversion curve by modifying a shape of said gradation conversion curve residing in a region other than a specific region, which serves as a fixed region including a predetermined position on said gradation conversion curve, based on said hardness adjusting value of said output-referred image data; and
wherein said first-changing section generates said second-revised gradation conversion curve by modifying a shape of said first-revised gradation conversion curve in such a manner that said specific region moves on a predetermined curve defined in advance, based on said brightness adjusting value.

33. The image-recording apparatus of claim 30, further comprising:
a determining section to determine a hardness adjusting value and a brightness adjusting value for said output-referred image data, corresponding to a specific combination of a kind of a subject to be included in said output image and an image-capturing condition;
wherein said first-changing section changes said gradation conversion curve to said first-revised gradation conversion curve, based on said hardness adjusting value determined by said determining section; and
wherein said second-changing section changes said first-revised gradation conversion curve to said second-revised gradation conversion curve, based on said brightness adjusting value determined by said determining section.

34. The image-recording apparatus of claim 30, further comprising:
a chroma-determining section to determine a chroma adjusting value for said output-referred image data, based on said hardness adjusting value determined by said hardness-determining section;
wherein said generating section generates said output-referred image data, based on said second-revised gradation conversion curve and said chroma adjusting value determined by said chroma-determining section.

35. The image-recording apparatus of claim 31, further comprising:
a chroma-determining section to determine a chroma adjusting value for said output-referred image data, based on said hardness adjusting value determined by said hardness-determining section;
wherein said generating section generates said output-referred image data, based on said second-revised gradation conversion curve and said chroma adjusting value determined by said chroma-determining section.

36. The image-recording apparatus of claim 33, further comprising:
a chroma-determining section to determine a chroma adjusting value for said output-referred image data, based on said hardness adjusting value determined by said hardness-determining section and said determining section;
wherein said generating section generates said output-referred image data, based on said second-revised gradation conversion curve and said chroma adjusting value determined by said chroma-determining section.

37. The image-recording apparatus of claim 31,
wherein said kind of subject is a portrait and said image-capturing condition is a backlight.

38. The image-recording apparatus of claim 32,
wherein, when said hardness adjusting value is set at zero, said brightness adjusting value is set at such a value that chroma components of said output-referred image data are emphasized.

39. The image-recording apparatus of claim 30,
wherein said kind of subject includes at least anyone of a portrait, a landscape and a still life.

40. The image-recording apparatus of claim 30,
wherein said image-capturing condition includes at least anyone of a backlight and a strobe lighting.

41. The image-processing method of claim 29,
wherein, when an input-output value of said gradation conversion curve is L*, said predetermined position included in said specific region is located at such a position that input value L* is smaller than 50 and equal to or greater than 40.

42. The image-recording apparatus of claim 29, further comprising:
a storage section to store initial values of hardness and brightness on said gradation conversion curve, which is defined for every outputting medium in advance, while correlating them with every one of users.

43. A computer program for executing operations for generating output-referred image data by applying an optimization processing, for optimizing an output image to be formed on an outputting medium, to scene-referred image data, said computer program comprising the functional steps of:
designating a hardness adjusting value for said output-referred image data;
changing a gradation conversion curve, which is defined for every outputting medium in advance and represents a conversion table for converting said scene-referred image data to said output-referred image data, based on said hardness adjusting value, so as to generate a first-revised gradation conversion curve;
designating a brightness adjusting value for said output-referred image data;
changing said first-revised gradation conversion curve, based on said brightness adjusting value, so as to generate a second-revised gradation conversion curve; and
generating said output-referred image data, based on said second-revised gradation conversion curve;
wherein said first-revised gradation conversion curve is generated by modifying a shape of said gradation conversion curve residing in a region other than a specific region, which serves as a fixed region including a predetermined position on said gradation conversion curve, based on said hardness adjusting value of said output-referred image data; and
wherein said second-revised gradation conversion curve is generated by modifying a shape of said first-revised gradation conversion curve in such a manner that said specific region moves on a predetermined curve defined in advance, based on said brightness adjusting value.

44. A computer program for executing operations for generating output-referred image data by applying an optimization processing, for optimizing an output image to be formed on an outputting medium, to scene-referred image data, said computer program comprising the functional steps of:
determining a hardness adjusting value for said output-referred image data, corresponding to a kind of a subject to be included in said output image;
changing a gradation conversion curve, which is defined for every outputting medium in advance and represents a conversion table for converting said scene-referred image data to said output-referred image data, based on said hardness adjusting value, so as to generate a first-revised gradation conversion curve;
determining a brightness adjusting value for said output-referred image data, corresponding to an image-capturing condition;
changing said first-revised gradation conversion curve, based on said brightness adjusting value, so as to generate a second-revised gradation conversion curve; and
generating said output-referred image data, based on said second-revised gradation conversion curve;
wherein said first-revised gradation conversion curve is generated by modifying a shape of said gradation conversion curve residing in a region other than a specific region, which serves as a fixed region including a predetermined position on said gradation conversion curve, based on said hardness adjusting value of said output-referred image data; and
wherein said second-revised gradation conversion curve is generated by modifying a shape of said first-revised gradation conversion curve in such a manner that said specific region moves on a predetermined curve defined in advance, based on said brightness adjusting value.

45. A computer program for executing operations for generating output-referred image data by applying an optimization processing, for optimizing an output image to be formed on an outputting medium, to scene-referred image data, said computer program comprising the functional steps of:
determining a hardness adjusting value and a brightness adjusting value for said output-referred image data, corresponding to a specific combination of a kind of a subject to be included in said output image and an image-capturing condition;
changing a gradation conversion curve, which is defined for every outputting medium in advance and represents a conversion table for converting said scene-referred image data to said output-referred image data, based on said hardness adjusting value, so as to generate a first-revised gradation conversion curve;
changing said first-revised gradation conversion curve, based on said brightness adjusting value, so as to generate a second-revised gradation conversion curve; and
generating said output-referred image data, based on said second-revised gradation conversion curve;
wherein said first-revised gradation conversion curve is generated by modifying a shape of said gradation conversion curve residing in a region other than a specific region, which serves as a fixed region including a predetermined position on said gradation conversion curve, based on said hardness adjusting value of said output-referred image data; and
wherein said second-revised gradation conversion curve is generated by modifying a shape of said first-revised gradation conversion curve in such a manner that said specific region moves on a predetermined curve defined in advance, based on said brightness adjusting value.

46. A computer program for executing operations for generating output-referred image data by applying an optimization processing, for optimizing an output image to be formed on an outputting medium, to scene-referred image data, said computer program comprising the functional steps of:
designating a hardness adjusting value for said output-referred image data;
changing a gradation conversion curve, which is defined for every outputting medium in advance and represents a conversion table for converting said scene-referred image data to said output-referred image data, based on said hardness adjusting value, so as to generate a first-revised gradation conversion curve;
designating a brightness adjusting value for said output-referred image data;
changing said first-revised gradation conversion curve, based on said brightness adjusting value, so as to generate a second-revised gradation conversion curve; and
determining a chroma adjusting value for said output-referred image data, based on said hardness adjusting value designated in said designating step;
generating said output-referred image data, based on said second-revised gradation conversion curve and said chroma adjusting value determined in said determining step;
wherein said first-revised gradation conversion curve is generated by modifying a shape of said gradation conversion curve residing in a region other than a specific region, which serves as a fixed region including a predetermined position on said gradation conversion curve, based on said hardness adjusting value of said output-referred image data; and
wherein said second-revised gradation conversion curve is generated by modifying a shape of said first-revised gradation conversion curve in such a manner that said specific region moves on a predetermined curve defined in advance, based on said brightness adjusting value.
